(19) United States
(12) Patent Application Publication
(10) Pub. No.: US 2024/0132412 A1
(43) Pub. Date: Apr. 25, 2024

(54) METHODS AND COMPOSITIONS FOR INCREASED THERMOELECTRIC OXIDE CERAMIC PERFORMANCE

(71) Applicant: West Virginia University Board of Governors on Behalf of West Virginia University, Morgantown, WV (US)

(72) Inventors: Xueyan SONG, Pittsburgh, PA (US); Cesar-Octavio ROMO-DE-LA-CRUZ, Morgantown, WV (US); Geoffroy GAUNEAU, Morgantown, WV (US); Liang LIANG, Morgantown, WV (US); Yun CHEN, Pittsburgh, PA (US)

(21) Appl. No.: 18/379,615

(22) Filed: Oct. 12, 2023

Related U.S. Application Data
(60) Provisional application No. 63/415,628, filed on Oct. 12, 2022.

(51) Int. Cl. C04B 35/624; C04B 35/50; C04B 35/626; C04B 35/64

(52) U.S. Cl. CPC C04B 35/624; C04B 35/50; C04B 35/6267; C04B 35/62675; C04B 35/62695; C04B 35/64; C04B 2235/3229

(57) ABSTRACT

In one aspect, the present disclosure relates to doped thermoelectric oxide ceramic compositions comprising stable cerium oxide nanoinclusions. In a further aspect, the thermoelectric oxide ceramic compositions comprise calcium cobaltite ceramic with a dopant, such as bismuth. The disclosed doped thermoelectric ceramic oxide compositions comprising ceramic oxide nanoinclusions have reduced thermal conductivity and an increased energy conversion efficiency as compared to a conventional doped thermoelectric oxide ceramic material without cerium oxide nanoninclusions. Also disclosed herein are methods for making the doped thermoelectric ceramic oxide compositions.

### CROSS-REFERENCE TO RELATED APPLICATIONS

This application claims the benefit of U.S. Provisional Application No. 63/415,628, filed on Oct. 12, 2022, which is incorporated herein by reference in its entirety.

### STATEMENT REGARDING FEDERALLY SPONSORED RESEARCH

This disclosure was made with U.S. Government support under grant number DMR 1916581, awarded by the National Science Foundation. The U.S. government has certain rights in the disclosure.

### BACKGROUND

While the reduction of the consumption of fossil energy and ultimate realization of zero-carbon emission has been urgently pursued, thermoelectric energy conversion represents one of the most promising technologies for generating clean energy using waste heat produced by various sources such as high-temperature solar thermal power plants (Refs. 2-3), and solid oxide cells for power generation and hydrogen production (Ref. 4-5). Thermoelectric materials and thermoelectric power generators convert a temperature difference into electrical energy directly (Refs. 6-10). The widespread applications of thermoelectric generations rely on high-performance and cost-effective thermoelectric materials. The energy conversion efficiency of the thermoelectric materials is characterized using the dimensionless Figure of Merit ZT, which is determined using the following equation of ZT=(S\hat{ }2 σT)/k, where S is the Seebeck coefficient, σ is the electrical conductivity (inverse of the electrical resistivity ρ), T is the temperature, and k is the thermal conductivity. To achieve high energy conversion efficiency, it is desired to have a low electrical resistivity, a high Seebeck coefficient, and a low thermal conductivity. A Figure of Merit ZT value of 1 corresponds to an energy conversion efficiency of 10%, which is believed to be acceptable for practical use in scaled operations.

Reduction of the thermal conductivity through the creation of the nanoscale intragranular defects such as precipitation and nano-inclusions could further increase the energy conversion efficiency ZT of oxide ceramics. Nevertheless, except for the precious metals, conventional compositions and methods have been unable to provide stable incorporation of extraneous oxide into desirable thermoelectric oxide ceramic materials such as Ca₃Co₄O_{9+δ}. Moreover, conventional compositions and methods have been unable to provide any dopants that can render the formation of nano-inclusions with controllable dimensions and density and do not impact the stoichiometry of the Ca₃Co₄O_{9+δ} matrix either.

Despite advances in research directed towards improved thermoelectric oxide ceramic materials, there remain a scarcity of attractive thermoelectric oxide ceramic materials, which are high-performance, e.g., a high ZT value, increased electrical power factor, and decreased thermal conductivity, and use cost-effective thermoelectric materials, e.g., such as Ca₃Co₄O_{9+δ} comprising defects such as precipitation and nano-inclusions. These needs and other needs are satisfied by the present disclosure.

### SUMMARY

In accordance with the purpose(s) of the disclosure, as embodied and broadly described herein, the disclosure, in one aspect, relates to doped thermoelectric oxide ceramic compositions comprising cerium oxide nanoinclusions. In a further aspect, the thermoelectric oxide ceramic compositions comprise calcium cobaltite ceramic with a dopant, such as bismuth. The disclosed doped thermoelectric ceramic oxide compositions comprising ceramic oxide nanoinclusions have an increased energy conversion efficiency as compared to conventional doped thermoelectric oxide ceramic materials without cerium oxide nanoninclusions. Also disclosed herein are methods for making the doped thermoelectric ceramic oxide compositions. Further disclosed herein are products and devices comprising the thermoelectric ceramic oxide compositions, e.g., solid-state conversion devices that can utilize heat to generate electricity.

Disclosed are processes to prepare a thermoelectric oxide ceramic material comprising nanoinclusions, the process comprising the steps of: (a) preparing an aqueous thermoelectric oxide ceramic precursor solution; (b) forming a thermoelectric oxide ceramic precursor sol-gel mixture from the thermoelectric oxide ceramic precursor solution; (c) heating the thermoelectric oxide ceramic precursor sol-gel mixture to form a thermoelectric oxide ceramic precursor ash; (d) preparing a thermoelectric oxide ceramic precursor powder using the thermoelectric oxide ceramic precursor ash; (e) calcining thermoelectric oxide ceramic precursor powder, thereby forming a calcined thermoelectric oxide ceramic precursor powder; (f) preparing a thermoelectric oxide ceramic-nanoinclusion precursor by mixing the calcined thermoelectric oxide ceramic precursor powder with cerium oxide nanoparticles; (g) forming pellets of the thermoelectric oxide ceramic-nanoinclusion precursor; and (h) sintering the pellets of the thermoelectric oxide ceramic-nanoinclusion precursor, thereby forming the thermoelectric oxide ceramic material comprising nanoinclusions; wherein the aqueous thermoelectric oxide ceramic precursor solution comprises two or more thermoelectric oxide ceramic precursor salts; wherein the two or more thermoelectric oxide ceramic precursor salts comprise two or more metal cations corresponding to two or more metals in the thermoelectric oxide ceramic; wherein the forming the thermoelectric oxide ceramic precursor sol-gel mixture comprises mixing a sol-gel polymer and a sol-gel acid with the aqueous thermoelectric oxide ceramic precursor solution; and wherein the forming pellets of the thermoelectric oxide ceramic-nanoinclusion precursor comprises applying pressure to the thermoelectric oxide ceramic-nanoinclusion precursor.

Also disclosed are thermoelectric oxide ceramic compositions prepared by the disclosed processes.

Also disclosed are thermoelectric oxide ceramic compositions comprising CeO nanoinclusions.

Also disclosed thermoelectric oxide ceramic are compositions comprising CeO nanoinclusions; wherein the composition comprises CaₓCo₄O_{9+δ}Bi_{y} and CeO; wherein x is about 2 to about 3; wherein y is about 0.1 to about 0.3; and wherein CeO is present in an amount of about 1 wt % to about 5 wt % based on the total weight of CaₓCo₄O_{9+δ}Bi_{y} and CeO.

Also disclosed are thermoelectric oxide ceramic compositions comprising CeO nanoinclusions; wherein the composition comprises Ca₃₋ₓCeₓCo₄O_{9+δ}; and wherein x is about 0.1 to 0.5.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described aspects are usable in all aspects of the disclosure taught herein. Furthermore, the individual features of the dependent claims, as well as all optional and preferred features and modifications of the described aspects are combinable and interchangeable with one another.

### BRIEF DESCRIPTION OF THE FIGURES

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 shows a representative XRD powder diffraction pattern for the Ca₃CeₓCo₄O_{9+δ} wherein x=0, 0.05, 0.1, 0.15, 0.3, 0.45 samples (indicated to the right of the applicable data trace).

FIGS. 2A-2F shows representative surface plan-view SEM images of disclosed Ca₃CeₓCo₄O_{9+δ} compositions having different cerium concentrations as follows: FIG. 2A shows a representative surface plan-view SEM image of Ca₃Co₄O_{9+δ}; FIG. 2B shows a representative surface plan-view SEM image of Ca_{2.95}Ce_{0.05}CO₄O_{9+δ}; FIG. 2C shows a representative surface plan-view SEM image of Ca_{2.9}Ce_{0.1}CO₄O_{9+δ}; FIG. 2D shows a representative surface plan-view SEM image of Ca_{2.85}Ce_{0.15}Co₄O_{9+δ}; FIG. 2E shows a representative surface plan-view SEM image of Ca_{2.7}Ce_{0.3}Co₄O_{9+δ}; and FIG. 2F shows a representative surface plan-view SEM image of Ca_{2.55}Ce_{0.45}Co₄O_{9+δ}.

FIGS. 3A-3F show representative fractured cross-section SEM images of disclosed Ca₃₋ₓCeₓCo₄O_{9+δ} compositions having different cerium concentrations as follows: FIG. 3A shows a representative fractured cross-section SEM image of Ca₃Co₄O_{9+δ}; FIG. 3B shows a representative fractured cross-section SEM image of Ca_{2.95}Ce_{0.05}Co₄O_{9+δ}; FIG. 3C shows a representative fractured cross-section SEM image of Ca_{2.9}Ce_{0.1}Co₄O_{9+δ}; FIG. 3D shows a representative fractured cross-section SEM image of Ca_{2.85}Ce_{0.15}Co₄O_{9+δ}; FIG. 3E shows a representative fractured cross-section SEM image of Ca_{2.7}Ce_{0.3}Co₄O_{9+δ}; and FIG. 3F shows a representative fractured cross-section SEM image of Ca_{2.55}Ce_{0.45}CO₄O_{9+δ}.

FIGS. 4A-4B show representative diffraction contrast TEM images obtained from a disclosed Ca_{2.9}Ce_{0.1}Co₄O_{9+δ} composition. FIG. 4A shows a representative low-magnification TEM image showing Ca_{2.9}Ce_{0.1}Co₄O_{9+δ} grains with a focus on grain boundaries. FIG. 4B shows a representative low-magnification TEM image showing nanoparticles and Ca_{2.9}Ce_{0.1}Co₄O_{9+δ} grains.

FIGS. 5A-5B show representative diffraction contrast TEM images from a disclosed Ca_{2.55}Ce_{0.45}Co₄O₉ composition. FIG. 5A shows a representative low-magnification TEM image showing nanoparticles and Ca_{2.55}Ce_{0.45}Co₄O₉ grains. FIG. 5B shows a representative TEM image showing nanoparticles and Ca_{2.55}Ce_{0.45}Co₄O₉ grain boundaries.

FIGS. 6A-6B show representative data pertaining to temperature dependence of the thermoelectric properties of a disclosed Ca₃₋ₓCeₓCo₄O₉ composition wherein x=0, 0.05, 0.1, 0.15, 0.3, 0.45 as indicated in the figures. FIG. 6A shows data pertaining to the Seebeck coefficient (S-T) of a disclosed Ca₃₋ₓCeₓCo₄O₉ composition wherein x=0, 0.05, 0.1, 0.15, 0.3, 0.45 as indicated in the figure. FIG. 6B shows data pertaining to the total thermal conductivity (k-T) of a disclosed Ca₃₋ₓCeₓCo₄O₉ composition wherein x=0, 0.05, 0.1, 0.15, 0.3, 0.45 as indicated in the figure.

FIGS. 7A-7C show representative XRD spectra of ground powders from sintered disclosed Ca₃Co₄O₉Bi_{0.25}+wt % CeOₓ compositions with the wt % of CeOₓ as indicated in the figure (“CCO+Bi_{0.25}+Xwt % CeOₓ”, where “Xwt %” is the wt % of CeOₓ) compared to control samples, Ca₃Co₄O₉ (“CCO”) and Ca₃Co₄O₉Bi_{0.25} (“CCO+Bi_{0.25}”), as indicated in the figure. The symbols * and + correspond to the CeOx and CoOx diffraction peaks, respectively. FIGS. 7A and 7B show the XRD spectrum. FIG. 7C shows a schematic representation of the lattice parameters calculated for Table 5.

FIGS. 8A-8B each show a representative diffraction contrast TEM image obtained from a disclosed Ca₃Co₄O_{9+δ}Bi_{0.25}+3 wt % CeOₓ composition show the nanostructure on the grain boundaries and grain interior of Ca₃Co₄O_{9+δ} and the morphology of CeOₓ nanoparticles. The figure indicates regions 1-8 that were sampled for EDS analysis shown in Table 5. The data show CeOₓ nanoparticles have a size of about 100-200 nm.

FIGS. 9A-9F show representative top surface view SEM images of disclosed sintered Ca₃Co₄O₉Bi_{0.25} compositions with different wt % concentrations of CeOₓ as follows: FIG. 9A shows representative top surface view SEM image of Ca₃Co₄O₉Bi_{0.25}+2 wt % CeOₓ; FIG. 9B shows representative top surface view SEM image of Ca₃Co₄O₉Bi_{0.25}+3 wt % CeOₓ; FIG. 9C shows representative top surface view SEM image of Ca₃Co₄O₉Bi_{0.25}+4 wt % CeOₓ; FIG. 9D shows representative top surface view SEM image of Ca₃Co₄O₉Bi_{0.25}+5 wt % CeOₓ; FIG. 9E shows representative top surface view SEM image of Ca₃Co₄O₉Bi_{0.25}+6 wt % CeOₓ; and FIG. 9F shows representative top surface view SEM image of Ca₃Co₄O₉Bi_{0.25}+8 wt % CeOₓ.

FIGS. 10A-10F show representative fractured internal surface view SEM images of disclosed sintered Ca₃Co₄O₉Bi_{0.25} compositions with different wt % concentrations of CeOₓ as follows: FIG. 10A shows representative fractured internal surface view SEM image of Ca₃Co₄O₉Bi_{0.25+}2 wt % CeOₓ; FIG. 10B shows representative fractured internal surface view SEM image of Ca₃Co₄O₉Bi_{0.25}+3 wt % CeOₓ; FIG. 10C shows representative fractured internal surface view SEM image of Ca₃Co₄O₉Bi_{0.25}+4 wt % CeOₓ; FIG. 10D shows representative fractured internal surface view SEM image of Ca₃Co₄O₉Bi_{0.25}+5 wt % CeOₓ; FIG. 10E shows representative fractured internal surface view SEM image of Ca₃Co₄O₉Bi_{0.25}+6 wt % CeOₓ; and FIG. 10F shows representative fractured internal surface view SEM image of Ca₃Co₄O₉Bi_{0.25+8} wt % CeOₓ.

FIGS. 11A-11E show representative data pertaining to temperature dependence of the thermoelectric properties of disclosed Ca₃Co₄O₉Bi_{0.25}+wt % CeOₓ compositions with the wt % of CeOₓ as indicated in the figure (“CCO+Bi_{0.25}+Xwt % CeOₓ”, where “Xwt %” is the wt % of CeOₓ) compared to control samples, Ca₃Co₄O₉ (“CCO”) and Ca₃Co₄O₉Bi_{0.25} (“CCO+Bi_{0.25}”), as indicated in the figure. The figures are as follows: FIG. 11A shows data pertaining to electrical resistivity for the samples as indicated; FIG. 11B shows data pertaining to the Seebeck coefficient (S-T) for the samples as indicated; FIG. 11C shows data pertaining to the electrical power factor (S²/ρ-T) for the samples as indicated; FIG. 11D shows data pertaining to the total thermal conductivity (K-T) for the samples as indicated; and FIG. 11E shows data pertaining to the thermoelectric figure of merit (ZT) for the samples as indicated.

FIG. 12 is a process flow chart outlining a representative disclosed process to prepare compositions according to the disclosure.

Additional advantages of the disclosure will be set forth in part in the description which follows, and in part will be obvious from the description, or can be learned by practice of the disclosure. The advantages of the disclosure will be realized and attained by means of the elements and combinations particularly pointed out in the appended claims. It is to be understood that both the foregoing general description and the following detailed description are exemplary and explanatory only and are not restrictive of the disclosure, as claimed.

### DETAILED DESCRIPTION

Many modifications and other aspects disclosed herein will come to mind to one skilled in the art to which the disclosed compositions and methods pertain having the benefit of the teachings presented in the foregoing descriptions and the associated drawings. Therefore, it is to be understood that the disclosures are not to be limited to the specific aspects disclosed and that modifications and other aspects are intended to be included within the scope of the appended claims. The skilled artisan will recognize many variants and adaptations of the aspects described herein. These variants and adaptations are intended to be included in the teachings of this disclosure and to be encompassed by the claims herein.

Although specific terms are employed herein, they are used in a generic and descriptive sense only and not for purposes of limitation.

As will be apparent to those of skill in the art upon reading this disclosure, each of the individual aspects described and illustrated herein has discrete components and features which may be readily separated from or combined with the features of any of the other several aspects without departing from the scope or spirit of the present disclosure.

Any recited method can be carried out in the order of events recited or in any other order that is logically possible. That is, unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present disclosure is not entitled to antedate such publication by virtue of prior disclosure. Further, the dates of publication provided herein can be different from the actual publication dates, which can require independent confirmation.

While aspects of the present disclosure can be described and claimed in a particular statutory class, such as the system statutory class, this is for convenience only and one of skill in the art will understand that each aspect of the present disclosure can be described and claimed in any statutory class.

It is also to be understood that the terminology used herein is for the purpose of describing particular aspects only and is not intended to be limiting. Unless defined otherwise, all technical and scientific terms used herein have the same meaning as commonly understood by one of ordinary skill in the art to which the disclosed compositions and methods belong. It will be further understood that terms, such as those defined in commonly used dictionaries, should be interpreted as having a meaning that is consistent with their meaning in the context of the specification and relevant art and should not be interpreted in an idealized or overly formal sense unless expressly defined herein.

Prior to describing the various aspects of the present disclosure, the following definitions are provided and should be used unless otherwise indicated. Additional terms may be defined elsewhere in the present disclosure.

### Definitions

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by”, “comprising,” “comprises”, “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.

As used herein, the term “and/or” includes any and all combinations of one or more of the associated listed items. Expressions such as “at least one of,” when preceding a list of elements, modify the entire list of elements and do not modify the individual elements of the list.

As used in the specification and the appended claims, the singular forms “a,” “an” and “the” include plural referents unless the context clearly dictates otherwise.

Reference to “a” chemical compound refers to one or more molecules of the chemical compound rather than being limited to a single molecule of the chemical compound. Furthermore, the one or more molecules may or may not be identical, so long as they fall under the category of the chemical compound. Thus, for example, “a” chemical compound is interpreted to include one or more molecules of the chemical, where the molecules may or may not be identical (e.g., different isotopic ratios, enantiomers, and the like).

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

When a range is expressed, a further aspect includes from the one particular value and/or to the other particular value. For example, where the stated range includes one or both of the limits, ranges excluding either or both of those included limits are also included in the disclosure, e.g., the phrase “x to y” includes the range from ‘x’ to ‘y’ as well as the range greater than ‘x’ and less than ‘y’. The range can also be expressed as an upper limit, e.g., ‘about x, y, z, or less’ and should be interpreted to include the specific ranges of ‘about x’, ‘about y’, and ‘about z’ as well as the ranges of ‘less than x’, less than y’, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y’, and ‘greater than z’. In addition, the phrase “about ‘x’ to ‘y’”, where ‘x’ and ‘y’ are numerical values, includes “about ‘x’ to about ‘y’”.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the terms “about,” “approximate,” “at or about,” and “substantially” mean that the amount or value in question can be the exact value or a value that provides equivalent results or effects as recited in the claims or taught herein. That is, it is understood that amounts, sizes, formulations, parameters, and other quantities and characteristics are not and need not be exact but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated ±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

As used herein, nomenclature for compounds, including organic compounds, can be given using common names, IUPAC, IUBMB, or CAS recommendations for nomenclature. When one or more stereochemical features are present, Cahn-Ingold-Prelog rules for stereochemistry can be employed to designate stereochemical priority, E/Z specification, and the like. One of skill in the art can readily ascertain the structure of a compound if given a name, either by systemic reduction of the compound structure using naming conventions, or by commercially available software, such as CHEMDRAW™ (Cambridgesoft Corporation, U.S.A.).

As used herein, the term “effective amount” refers to an amount that is sufficient to achieve the desired modification of a physical property of the composition or material

As used herein, the terms “optional” or “optionally” means that the subsequently described event or circumstance can or cannot occur, and that the description includes instances where said event or circumstance occurs and instances where it does not.

As used herein, “ZT” and “Figure of Merit ZT” can be used interchangeably and refer to a dimensionless quantity calculated using the following equation of ZT=(S²σT)/k, where S is the Seebeck coefficient, a is the electrical conductivity (inverse of the electrical resistivity p), T is the temperature, and k is the thermal conductivity. A ZT of 1 corresponds to an energy conversion efficiency of 10%.

It is understood herein throughout that reference to a metal, e.g., Ba, is inclusive of any oxidation state consistent with the context or given formula.

Unless otherwise specified, temperatures referred to herein are based on atmospheric pressure (i.e., one atmosphere).

### INTRODUCTION

While the reduction of the consumption of fossil energy and ultimate realization of zero-carbon emission has been urgently pursued, the thermoelectric energy (TE) conversion (Ref. 1) represents one of the most promising technologies for generating clean energy using waste heat produced by various sources such as high-temperature solar thermal power plants (Refs. 2-3) and solid oxide cells for power generation and hydrogen production (Refs. 4-5). Thermoelectric materials and thermoelectric power generators convert a temperature difference into electrical energy directly (Refs. 6-10). The widespread application of thermoelectric power generation will only occur by being able to rely on high-performance and cost-effective thermoelectric materials.

The energy conversion efficiency of the thermoelectric materials is characterized using the dimensionless Figure of Merit ZT (“ZT”). ZT is determined using the following equation of ZT=(S²σT)/k, where S is the Seebeck coefficient, a is the electrical conductivity (inverse of the electrical resistivity ρ), T is the temperature, and k is the thermal conductivity. To achieve high energy conversion efficiency, it is desired to have a low electrical resistivity, a high Seebeck coefficient, and a low thermal conductivity. A ZT of 1 corresponds to an energy conversion efficiency of 10%, which is acceptable for practical application.

Among the promising p-type promising thermoelectric oxide, the BiCuSeO is reported to have a high thermoelectric ZT of 1.4 (Ref. 11) at 923K. Nevertheless, BiCuSeO-based TE materials cannot be used in the air due to their thermal decomposition in the air above 523K (Ref. 12-14). In comparison to BiCuSeO, misfit layered calcium cobaltite Ca₃Co₄O_{9+δ} oxide is an auspicious p-type TE oxide (Refs. 6, 7, 9, 15, 16, 17). A calcium cobaltite Ca₃Co₄O_{9+δ} oxide single crystal exhibits an extrapolated ZT of 0.87 at 973K (18) and is exceptionally stable up to 1199K (Ref. 19) in the air and over 1253 K in an oxygen atmosphere (Ref. 20). Due to high thermal stability, non-toxicity, and lightweight, if such cost-effective and environmentally benign polycrystalline ceramics could be processed and engineered to achieve the performance of that of the single crystals, Ca₃Co₄O_{9+δ} oxide materials could expand the current niche markets where reliability are more important than the cost and performance and promote the large-scale commercial applications of thermoelectric ceramics in terms both power generation and thermal management.

Other recent studies have demonstrated that with simultaneous intragranular dopants substitution and intergranular dopants segregation at the grain boundaries, the polycrystalline Ca₃Co₄O_{9+δ} based ceramics achieved the high ZT of 0.9 at 1073K and outperformed the single crystals (Ref. 21). The ZT is increased to about 260% at 1073K. This is mainly achieved by increasing the electrical power factor (460% at 310 K and about 230% at 1073K) by simultaneously increasing the electrical Seebeck coefficient and electrical conductivity, while the thermal conductivity is decreased by only ˜10%. This is entirely different from what has been achieved for state-of-the-art semiconducting thermoelectric materials that were enabled by reducing the thermal conductivity nanostructure engineering rather than improvement in power factors (Ref. 22).

During the past two decades, nanostructure engineering through point defects, interface and grain boundary engineering, and nano-inclusions have been developed to reduce the thermal conductivity of various thermoelectric materials, including bismuth telluride and silicon-germanium (Ref. 22). In particular, for bulk materials, a major reduction of the thermal conductivity may derive from two types of nanostructure engineering: nanocrystalline and materials with self-formed inhomogeneities on nanoscale driven by phase separation such as spinodal decomposition and nucleation and growth. When introduced to a matrix with appropriate dimensions and spacing, such particles may lead to a dramatic reduction in the thermal conductivity by as much as a factor of 3. For example, in an Ag—Pb—Sn—Sb—Te-based material, a significant decrease of thermal conductivity from 1.5 W/(mK) to 0.5 W/(mK) was attributed to the creation of 3-20 nm dense nano precipitates with an average spacing of 20 nm (Ref. 23).

The above materials comprising intragranular dopants substitution and intergranular dopants segregating at the grain boundaries of oxide ceramics already outperform the single crystals, leading to the oxide ceramics with ZT of 0.9 (Ref. 21). If nanoprecipitates similar to what has been developed for Ag—Pb—Sn—Sb—Te-based materials could be applied to the misfit-layered oxide of polycrystalline Ca₃Co₄O_{9+δ} based ceramics, the further reduction of the thermal conductivity could boost the energy conversion efficiency ZT of oxide ceramics over 1, which is the benchmark threshold for commercial applications.

Despite advances in creating such nanoparticles, combining thermodynamically stable nanoparticles into dense solid bulk oxide ceramics is not straightforward. Although nanoprecipitates have been proven to be one of the effective and feasible approaches for reducing thermal conductivity and increasing energy conversion efficiencies, the incorporation of the nano-inclusions into the Ca₃Co₄O_{9+δ} has been proven to be very challenging. In general, the Ca₃Co₄O_{9+δ} is very reactive and many commonly used dopants have unacceptable solubilities in it. Several attempts have been made to introduce nano inclusions, such as silver (Refs. 24-25), CoOₓ (Ref. 26), NaCoOₓ, ZrO₂ (Ref. 27), SiOₓ, or SiC (Ref. 28) into Ca₃Co₄O_{9+δ}. Of these, Ag and CoOₓ remain in a pure phase without alloying with Ca and/or Co. The other materials listed yield inclusions react with Ca₃Co₄O_{9+δ} and destroy the integrity of the stoichiometry of the Ca₃Co₄O_{9+δ} lattice. As such, these materials increase both electrical resistivity and thermal conductivity. Moreover, none of the foregoing materials have resulted in nano-inclusions with controllable density distribution, a necessary requirement to controllably achieve a significant reduction of the thermal conductivity of oxide ceramics. In short, conventional compositions and methods have been unable to create a thermodynamically stable oxide nano-precipitation that is either miscible or has the appropriate solubility with Ca₃Co₄O_{9+δ}.

It is notable that the disclosed compositions and methods utilize nontoxic oxide materials having extremely low costs (only 5-10% of SiGe and BiTe; Ref. 36). It is believed that the disclosed compositions can be prepared utilizing methods that are low cost and can be readily scaled up for large-scale production. In practical applications, the thermoelectric oxide ceramic must operate for years at high temperatures to maximize efficiency, and thermal stability is an important issue for state-of-the-art TE materials that are heavily engineered to be nanostructure. A significant challenge, which has heretofore gone unmet, is to produce a thermodynamically stable material that can retain its nanostructure while being used in a practical device. If the nanostructure spontaneously dissolves during the operation, the TE performance will return to those of the bulk material, removing any increase in efficiency that the nanostructured material was supposed to give. For most TE materials, creating a stable nanostructure is difficult because the nanostructured form is not an equilibrium state of the material. Diffusion and energy related to the interface often act to remove the nanoscale structure or the variation in compositions.

In various aspects, the present disclosure provides a thermoelectric oxide ceramic material that comprises at the solubility limit a Ce saturated Ca₃Co₄O_{9+δ} lattice with a constant electrical power factor and a lowered thermal conductivity from baseline ceramics. In a further aspect, e.g., as shown in the Examples of Ca₃₋ₓCeₓCo₄O_{9+δ} samples, when the solubility limit is reached, further substitution of the Ce resulted in the formation of the CaO, CoOₓ, and the CeOₓ. In a still further aspect, e.g., as shown in the Examples of Ca₃₋ₓCeₓCo₄O_{9+δ} samples, the disclosed compositions and methods are associated with pure CeO, precipitation with a well-bonded interface with Ca₃Co₄O_{9+δ} grains. In a yet further aspect, the disclosed compositions and methods provide a calcium cobaltite comprising thermodynamically stable CeOₓ, and due to the insolubility of Ca and Co within the CeOₓ, the direct mixing of CeOₓ into the calcined Ca₃Co₄O_{9+δ} provides an approach to form the stable nanoparticles embedded within the Ca₃Co₄O_{9+δ} matrix. In an even further aspect, the disclosed methods and compositions allow for control of nanoparticle size and distribution via sintering. The Examples herein below show that the nano-precipitates are with a dimension larger than the mean free path of carriers, thereby allowing for stable CeO, that could be encapsulated in the Ca₃Co₄O_{9+δ} matrix.

### Thermoelectric Ceramic Oxide Compositions Comprising CeOₓ Nano-Inclusions

In accordance with the purpose(s) of the disclosure, as embodied and broadly described herein, the disclosure, in one aspect, relates to thermoelectric materials comprising CeOₓ nano precipitates in Ca₃Co₄O_{9+δ}. In another aspect, the materials can comprise CeOₓ nano precipitates in Ca_{3-z}CeₓCo₄O_{9+δ}, where z is about 0.05 to 0.5, about 0.1 to 0.5, about 0.05 to 0.45, about 0.15 to 0.35, or about 0.1 to 0.3. In further aspects, CeOₓ is CeO.

In another aspect, the significance of such thermodynamically stable nano-precipitation is further exemplified by introducing identified CeOₓ precipitates as extraneous inclusions into a Bi-doped CaₓCo₄O_{9+δ}, where z is about 2 to about 3, with well-understood intragranular and intergranular structure. In a further aspect, the Bi-doped material can comprise CaₓCo₄O_{9+δ}Bi_{y} and CeOₓ, where y is about 0.01 to about 0.4, about 0.1 to about 0.3, or about 0.25 and where CeOₓ is present in an amount of about 1 wt % to about 5 wt %, about 2 wt % to about 4 wt %, or about 3 wt % based on the total weight of CaₓCo₄O_{9+δ}Bi_{y} and CeOₓ. In still further aspects, the Bi-doped material comprises Ca₃Co₄O_{9+δ}Bi_{0.25}. In some aspects, the Bi-doped material comprises CaₓCo₄O_{9+δ}Bi_{y}, as defined above, with 0 wt % CeOₓ or Ca₃Co₄O_{9+δ}Bi_{0.25} with 0 wt % CeOₓ. In some aspects, CeOₓ is CeO₂.

In another aspect, a Bi-doped material without CeOₓ nano precipitates (e.g., CaₓCo₄O_{9+δ}Bi_{y}, as defined previously, or Ca₃Co₄O_{9+δ}Bi_{0.25}) can have a Figure of Merit ZT value of about 0.70 to about 1.00 at about 1073K or at 1073K. In a further aspect, the CeOₓ nano precipitates in Ca₃Co₄O_{9+δ} ceramics have unexpectedly high ZT compared to Ca₃Co₄O_{9+δ} single crystals over a wide range of temperatures, for example, from 273K to 1200K. In other aspects, the Bi-doped material at a temperature of about 323K or at 323K can have an electrical power factor of about 2.2 to 4.0 mW/K²m, about 2.30 to 2.70 mW/K²m, about 2.50 to 2.60 mW/K²m, or about 2.57 mW/K²m and a thermal conductivity of about 1.50 to 1.90 W/(mK), about 1.60 to 1.80 W/(mK), or about 1.71 W/(mK). In yet further aspects, this Bi-doped material at a temperature of about 1073K or at 1073K can have an electrical power factor of about 0.5 to 2.0 mW/K²m, about 0.60 to 1.00 mW/K²m, about 0.70 to 0.90 mW/K²m, or about 0.86 mW/K²m and a thermal conductivity of about 1.30 to 1.70 W/(mK), about 1.40 to 1.60 W/(mK), or about 1.53 W/(mK). In still further aspects, in comparison with a baseline, a Bi-doped Ca₃Co₄O_{9+δ} with nominal chemistry of Ca₃Co₄O_{9+δ}Bi_{0.25} at a temperature of about 1073K or at 1073K has an increased electrical power factor (from 0.603 to 0.9159 mW/K²m) and comparison of thermal conductivity of 1.53 W/(mK). In yet further aspects, in comparison with a baseline, a Bi-doped Ca₃Co₄O_{9+δ} with nominal chemistry of Ca₃Co₄O_{9+δ}Bi_{0.25} at a temperature of about 1073K or at 1073K has an increased electrical power factor (from 0.603 to 0.86 mW/K²m) and comparison of thermal conductivity of 1.53 W/(mK).

In another aspect, the Bi-doped material that does comprise CeO, nano precipitates (e.g., CaₓCo₄O_{9+δ}Bi_{y}+wt % CeOₓ, as defined previously, or Ca₃Co₄O_{9+δ}Bi_{0.25} wt % CeOₓ) can have a Figure of Merit ZT value of about 1.05 to about 1.30 at about 1073K or at 1073K. In further aspects, the Figure of Merit ZT value at about 1073K or at 1073 K can be greater than or equal to about 1.0, greater than or equal to about 1.1, greater than or equal to about 1.2, or about 1.25. In further aspects, the Bi-doped material with nano-inclusions at a temperature of about 323K or at 323K can have an electrical power factor of about 1.5 to 3.0 mW/K²m, about 1.60 to 2.00 mW/K²m, about 1.70 to 1.90 mW/K²m, or about 1.84 mW/K²m and a thermal conductivity of about 1.40 to 1.80 W/(mK), about 1.50 to 1.70 W/(mK), less than or equal to about 1.7 W/(mK), or about 1.66 W/(mK). In yet further aspects, this Bi-doped material at a temperature of about 1073K or at 1073K can have an electrical power factor of about 1.3 to 3.0 mW/K²m, about 1.40 to 1.80 mW/K²m, about 1.50 to 1.70 mW/K²m, or about 1.60 mW/K²m and a thermal conductivity of about 1.10 to 1.50 W/(mK), about 1.20 to 1.40 W/(mK), less than or equal to about 1.40 W/(mK), or about 1.35 W/(mK). In another aspect, the addition of such nano-inclusions and the related intra-granular doping of a Bi-doped Ca₃Co₄O_{9+δ} with nominal chemistry of Ca₃Co₄O_{9+δ}Bi_{0.25} at a temperature of about 1073K or at 1073K leads to the further increase of electrical power factor (from 0.9159 to 1.5336 mW/K²m) and simultaneous decrease of the thermal conductivity (from 1.53 to 1.35 W/mK), and the ZT of 1.25 at 1073K, the highest ZT ever reported for all kinds of thermoelectric oxide ceramics at elevated temperatures e.g., 1073K.

In another aspect, a method of preparing the CeO, nano precipitates in Ca₃Co₄O_{9+δ} is described. In another aspect, a method of preparing the CeOₓ nano precipitates in bismuth-doped CaₓCo₄O_{9+δ}, where z is about 2 to about 3, (e.g., Bi-doped Ca₃Co₄O_{9+δ}) is described.

### Methods of Making Disclosed Thermoelectric Ceramic Oxide Compositions Comprising Nano-Inclusions

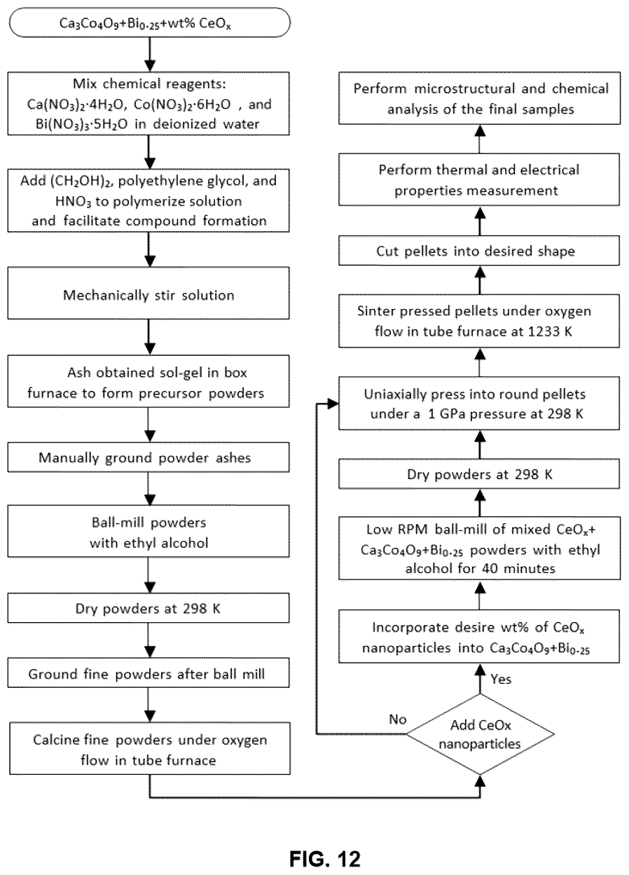

With reference to FIG. 12, the present disclosure pertains to a method to prepare compositions as set out in this specification. In an aspect, a CaₓCo₄O_{9+δ}Bi_{y}+wt % CeOₓ composition may be prepared by multistep process including mixing, multiple heating steps, milling, uniaxial pressure, and sintering, where y is about 0.01 to about 0.4, about 0.1 to about 0.3, or about 0.25 and where CeOₓ is present in an amount of about 1 wt % to about 5 wt %, about 2 wt % to about 4 wt %, or about 3 wt % based on the total weight of CaₓCo₄O_{9+δ}Bi_{y} and CeOₓ. In further aspects, this composition can be Ca₃Co₄O₉+Bi_{0.25}+3 wt % CeOₓ. In another aspect, a Ca_{3-z}CeₓCo₄O_{9+δ} composition may be prepared by multistep process including mixing, multiple heating steps, milling, uniaxial pressure, and sintering, where z is about 0.05 to 0.5, about 0.1 to 0.5, about 0.05 to 0.45, about 0.15 to 0.35, or about 0.1 to 0.3. In some aspects, CeOₓ is CeO₂.

In an aspect, an aqueous thermoelectric oxide ceramic precursor solution is prepared including at least two or more thermoelectric oxide ceramic precursor salts. In a further aspect, the thermoelectric oxide ceramic precursor salts can include two or more metal cations corresponding to the two or more metal cations present in the thermoelectric oxide ceramic material. In yet a further aspect, the thermoelectric oxide ceramic precursor salts can be selected from a calcium salt, a cobalt salt, or a bismuth salt, optionally further including a nitrate anion. In an aspect, calcium, cobalt, and bismuth salts are admixed in de-ionized water in proportions as needed. Such salts may be used in hydrated or unhydrated forms. For example, Ca(NO₃)₂·4H₂O, Co(NO₃)₂·6H₂O, and Bi(NO₃)₃·5H₂O may be mixed in deionized water.

In an aspect, the admixture is converted to a sol-gel by a method known to those of ordinary skill in the art. For example, a glycol, for example ethylene glycol, diethylene glycol, or a polyethylene glycol may be added to the admixture. A strong acid may also be added, for example nitric acid and/or sulfuric acid. In a further aspect, the process of forming the sol-gel mixture can also include mixing a sol-gel precursor with the thermoelectric oxide ceramic precursor solution. The sol-gel precursor can include ethylene glycol.

In an aspect, the sol-gel may be fired as known to those of ordinary skill in the art, for example, by a box oven, to obtain an ash. The firing or heating can occur at temperatures of about 400° C. to about 600° C., about 400° C. to about 500° C., about 500° C. to about 600° C., about 450° C. to about 550° C., or about 500° C. In an aspect, the ashes may be ground and/or milled to a chosen particle size. The milling may be done by any such method known to those of ordinary skill in the art, for example, ball milling. Milling may be affected by dry milling or wet milling, as understood by a person of ordinary skill in the art. Wet milling may be in a suitable carrier, e.g., water, or a normal alcohol, for example, ethanol. In an aspect, the resulting powder after milling may be dried and/or ground further using a method known to a person of ordinary skill in the art.

In an aspect, the resulting milled powder may be calcined in the presence of oxygen in an appropriate furnace, for example, a tube furnace to provide Ca₃Co₄O_{9+δ}+Bi_{0.25}. In a further aspect, the milled powder can be calcined at a temperature of about 600° C. to about 800° C., about 600° C. to about 700° C., about 700° C. to about 800° C., about 650° C. to about 750° C., or about 700° C. In an aspect, this material is uniaxially pressed to provide pellets, e.g., round pellets, under a high-pressure press, where the pressure applied is about 0.5 GPa to about 2 GPa, about 0.75 GPa to about 1.75 GPa, or about or equal to 1 GPa, at atmospheric temperature, for example 273K. The pellets may be sintered under oxygen flow at very high temperatures, e.g., from 1000K to 1400K, from 1000K to 1300K, from 1200K to 1250K, or about 1233K.

Alternatively, in an aspect, Ca_{z}Co₄O_{9+δ}Bi_{y} or, in a further aspect, Ca₃Co₄O_{9+δ}+Bi_{0.25} may be admixed with CeOₓ nanoparticles in a desired weight percent. Such weight percentages of CeOₓ nanoparticles may be from about 0.5 to about 4% weight percent of Ca_{z}Co₄O_{9+δ}Bi_{y}+CeOₓ or Ca₃Co₄O_{9+δ}+Bi_{0.25}+CeOₓ. In some aspects, the weight percent of CeOₓ nanoparticles is about 3%. The admixture may be milled as needed by the person of ordinary skill to provide a powder that is subsequently dried at room temperature, e.g., 298K.

In an aspect, the Ca₃Co₄O_{9+δ}+Bi_{0.25}+CeOₓ milled powder is uniaxially pressed to provide pellets, e.g., round pellets, under a high-pressure press, e.g., at 1 GPa, at atmospheric temperature, for example 273K. The pellets may be sintered at very high temperatures, e.g., from 1000K to 1300K under oxygen flow.

### Methods of Using the Disclosed Thermoelectric Oxide Ceramic Compositions

In various aspects, the present disclosure relates to methods of using the disclosed thermoelectric ceramic oxide compositions in various systems and products in which heat, including both waste heat, intentionally generated heat, or uncaptured heat, in a system is converted to electricity using a solid-state conversion device comprising a disclosed thermoelectric ceramic oxide composition. The disclosed solid-state conversion device can further comprise components such as, but not limited to DC-DC inverters, DC regulators, rechargeable batteries, and the like.

In a further aspect, the present disclosure pertains to a method of generating an electrical current, the method comprising a solid-state conversion systems and devices comprising a disclosed thermoelectric ceramic oxide composition.

In various aspects, disclosed herein are solid-state conversion systems and devices comprising a disclosed thermoelectric ceramic oxide composition. In further various aspects, disclosed herein are solid-state conversion systems and devices comprising a disclosed thermoelectric ceramic oxide composition made by a disclosed method of making the disclosed thermoelectric ceramic oxide compositions.

In a further aspect, disclosed herein are a devices and systems comprising a solid-state energy conversion device comprising one or more disclosed thermoelectric ceramic oxide composition to provide electricity from heat generated in the product or system. Exemplary, but non-limiting examples include a system comprising a solid-state energy conversion device comprising one or more disclosed thermoelectric ceramic oxide composition that utilizes the heat radiation from a steel forming process; a system comprising a solid-state energy conversion device comprising one or more disclosed thermoelectric ceramic oxide composition that utilizes waste heat recovery in an automobile, such as recovery of energy from an exhaust system; a system comprising a solid-state energy conversion device comprising one or more disclosed thermoelectric ceramic oxide composition that utilizes heat radiation from a diesel marine engine; a system comprising a solid-state energy conversion device comprising one or more disclosed thermoelectric ceramic oxide composition that utilizes heat generated in a hypersonic vehicle; a system comprising a solid-state energy conversion device comprising one or more disclosed thermoelectric ceramic oxide composition that utilizes heat energy from a power generation system, e.g., a nuclear power system, wherein the electricity generated is provided to power a sensor, wherein the sensor comprises a wireless transmitter device to transmit data from the sensor; a system comprising a solid-state energy conversion device comprising one or more disclosed thermoelectric ceramic oxide composition that utilizes heat generated in an unmanned aerial vehicle (UAV), wherein the electricity provided by the solid-state conversion device allows for extended range and capabilities of the UAV; a system comprising a solid-state energy conversion device comprising one or more disclosed thermoelectric ceramic oxide composition that utilizes heat generated by solid oxide electrolysis cells (SOEC), solid oxide fuel cell (SOFC), including, but not limited, to SOFCs as known to the skilled artisan, such as a molten carbonate fuel cell; and a system comprising a solid-state energy conversion device comprising one or more disclosed thermoelectric ceramic oxide composition that utilizes heat from a stationary diesel plant, solid-fuel stove, gas residential biomass boiler, and the like.

In various aspects, the present disclosure relates to products comprising the disclosed thermoelectric ceramic oxide compositions. The products comprising the disclosed thermoelectric ceramic oxide compositions are components or assemblies in a solid-state conversion device designed to convert heat, including both waste heat, intentionally generated heat, or uncaptured heat is converted to electricity, such as the examples disclosed herein above. The disclosed solid-state conversion device can further comprise components such as, but not limited to DC-DC inverters, DC regulators, rechargeable batteries, and the like.

### REFERENCES

References are cited herein throughout using the format of reference number(s) enclosed by parentheses corresponding to one or more of the following numbered references. For example, citation of references numbers 1 and 2 immediately herein below would be indicated in the disclosure as (Refs. 1-2).
(1) He J, Tritt T M. Advances in thermoelectric materials research: Looking back and moving forward. Science. 2017; 357 (6358):eaak9997.
(2) Karimi, Marzie and Mehdi Mehrpooya. “Proposal and Investigation of a Novel Hybrid Hydrogen Production and Liquefaction Process Using Solid Oxide Electrolyzer, Solar Energy, and Thermoelectric Generator.” Journal of Cleaner Production 331, (2022): 130001.
(3) Abdelkareem, Mohammad Ali, Mohamed S Mahmoud, Khaled Elsaid, Enas Taha Sayed, Tabbi Wilberforce, Mohammed Al-Murisi, Hussein M Maghrabie and AG Olabi. “Prospects of Thermoelectric Generators with Nanofluid.” Thermal Science and Engineering Progress, (2022): 101207.
(4) Hauch, Anne, R Kungas, P Blennow, A B Hansen, J B Hansen, BV Mathiesen and Mogens Bjerg Mogensen. “Recent Advances in Solid Oxide Cell Technology for Electrolysis.” Science 370, no. 6513 (2020).
(5) Chen, Yun, Cesar O. Romo-De-La-Cruz, Sergio A. Paredes-Navia, Liang Liang, Alec Hinerman, Jacky Prucz, Mark Williams and Xueyan Song. “Electrocatalytic Surface Nanoionics with Strained Interfaced and Colossal Conductivity for Enhancing Durability and Performance of Solid Oxide Fuel Cell.” Journal of Power Sources 517, (2022): 230715.
(6) Wolf, M., et al. (2019). “High Power Factor vs. High zT-A Review of Thermoelectric Materials for High-Temperature Application.” Entropy 21(11): 1058.
(7) Brown, S. R.; Kauzlarich, S. M.; Gascoin, F.; Snyder, G. J. Yb14MnSb11: New High Efficiency Thermoelectric Material for Power Generation. Chem. Mater. 2006, 18, 1873-1877.
(8) Funahashi, R., et al. (2015). “Thermoelectric materials for middle and high-temperature ranges.” Journal of Materials Research 30(17): 2544-2557.
(9) A. C. Masset, C. Michel, A. Maignan, M. Hervieu, O. Toulemonde, F. Studer, B. Reveau, J. Hejtmanek Phys. Rev. B, 62 (2000), p. 166
(10) He J, Liu Y, Funahashi R. Oxide thermoelectrics: The challenges, progress, and outlook. J Mater Res. 2011; 26(15):1762.
(11) Pei, Y. L., et al. (2014). “High thermoelectric performance realized in a BiCuSeO system by improving carrier mobility through 3D modulation doping.” Journal of the American Chemical Society 136(39): 13902-13908.
(12) Selvan, K. V., et al. (2019). “State-of-the-Art Reviews and Analyses of Emerging Research Findings and Achievements of Thermoelectric Materials over the Past Years.” Journal of Electronic Materials 48(2): 745-777.
(13) Sato, T., et al. (2016). “Thermoelectric Properties and Thermal Stability of BiCuSeO.” Journal of Electronic Materials 45(11): 5521-5525.
(14) Barreteau C, Berardan D, Dragoe N. Studies on the thermal stability of BiCuSeO. J Solid State Chem. 2015; 222:53-9.
(15) J. Androulakis, P. Migiakis, and J. Giapintzakis, Appl. Phys. Lett. 84, 1099 2004
(16) Boyle, C., et al. (2016). “Grain boundary segregation and thermoelectric performance enhancement of bismuth doped calcium cobaltite.” Journal of the European Ceramic Society 36(3): 601-607.
(17) Song, X. Y., et al. (2012). “Significant enhancement of electrical transport properties of thermoelectric Ca3Co4O9+delta through Yb doping.” Solid State Communications 152(16): 1509-1512.
(18) Shikano, M. and R. Funahashi (2003). “Electrical and thermal properties of single-crystalline (Ca₂CoO₃)_{(0.7)}CoO₂ with a Ca₃Co₄O₉ structure.” Applied Physics Letters 82(12): 1851-1853.
(19) Woermann, E., & Muan, A. (1970). Phase equilibria in the system CaO-cobalt oxide in air. Journal of Inorganic and Nuclear Chemistry, 32(5), 1455-1459.
(20) Boyle C, Liang L, Romo-De-La-Cruz C O, Johnson R, Chen Y, Prucz J, et al. Improving the thermoelectric performance and thermal stability of Ca 3 Co 4 O 9+δ ceramics by sintering in oxygen atmosphere. Journal of Sol-Gel Science and Technology. 2018; 85(3):712-22.
(21) Romo-De-La-Cruz, Cesar-Octavio, Yun Chen, Liang Liang, Mark Williams and Xueyan Song. “Thermoelectric Oxide Ceramics Outperforming Single Crystals Enabled by Dopant Segregations.” Chemistry of Materials 32, no. 22 (2020): 9730-9739.
(22) Kanatzidis M G. Nanostructured thermoelectrics: the new paradigm? Chem Mat. 2009; 22(3):648-59.
(23) Poudeu, P. F. P.; D'angelo, J.; Downey, A. D.; Short, J. L.; Hogan, T.; Kanatzidis, M. G. Angew. Chem., Int. Ed. 2006, 45, 3835.
(24) Van Nong, N. (2011). “Enhancement of the Thermoelectric Performance of p-Type Layered Oxide Ca3Co4O9+ Through Heavy Doping and Metallic Nanoinclusions.” Advanced Materials 23(21): 2484.
(25) Zhang, F., et al. (2009). “Texture and high-temperature transport properties of AgxCa3-xCo4O9 (0≤x≤0.6) compounds.” Journal of Alloys and Compounds 477(1-2): 543 546.
(26) Delorme F, Diaz-Chao P, Guilmeau E, Giovannelli F. Thermoelectric properties of Ca3Co4O9-Co3O4 composites. Ceram Int. 2015; 41(8):10038-43.
(27) Gupta, R. K., et al. (2016). “The effect of ZrO₂ dispersion on the thermoelectric power factor of Ca3Co4O9.” Physica B: Condensed Matter 483: 48-53.
(28) Wang, X., et al. (2019). “Significant enhancement in Seebeck coefficient and power factor of Ca3Co4O9 thermoelectric ceramics by SiC addition.” Journal of Alloys and Compounds 785: 698-705.
(29) Carvillo P, Chen Y, Boyle C, Barnes P N, Song X. Thermoelectric Performance Enhancement of Calcium Cobaltite through Barium Grain Boundary Segregation. Inorg Chem. 2015; 54(18):9027-32.
(30) Romo-De-La-Cruz, C. O., Chen, Y., Liang, L., Williams, M., & Song, X. (2020). Thermoelectric oxide ceramics outperforming single crystals enabled by dopant segregations. Chemistry of Materials, 32(22), 9730-9739.
(31) Romo-De-La-Cruz, C., Liang, L., Navia, S. P., Chen, Y., Prucz, J., & Song, X. (2018). Role of oversized dopant potassium on the nanostructure and thermoelectric performance of calcium cobaltite ceramics. Sustainable Energy & Fuels, 2(4), 876-881.
(32) Dake, J. M., Oddershede, J., Sørensen, H. O., Werz, T., Shatto, J. C., Uesugi, K., . . . & Krill, C. E. (2016). Direct observation of grain rotations during coarsening of a semisolid Al—Cu alloy. Proceedings of the National Academy of Sciences, 113(41), E5998-E6006.
(33) Pakdel, A., Guo, Q., Nicolosi, V., & Mori, T. (2018). Enhanced thermoelectric performance of Bi—Sb—Te/Sb 2 O 3 nanocomposites by energy filtering effect. Journal of Materials Chemistry A, 6(43), 21341-21349.
(34) Alleno, E., Chen, L., Chubilleau, C., Lenoir, B., Rouleau, O., Trichet, M. F., & Villeroy, B. (2010). Thermal conductivity reduction in CoSb3-CeO2 nanocomposites. Journal of electronic materials, 39(9), 1966-1970.
(35) Suzuki, K., Kato, M., Sunaoshi, T., Uno, H., Carvajal-Nunez, U., Nelson, A. T., & McClellan, K. J. (2019). Thermal and mechanical properties of CeO2. Journal of the American Ceramic Society, 102(4), 1994-2008.
(36) LeBlanc, Saniya, Shannon K Yee, Matthew L Scullin, Chris Dames and Kenneth E Goodson. “Material and Manufacturing Cost Considerations for Thermoelectrics.” Renewable and Sustainable Energy Reviews 32, (2014): 313-327.

### Aspects

The following listing of exemplary aspects supports and is supported by the disclosure provided herein.

Aspect 1. A process to prepare a thermoelectric oxide ceramic material comprising nanoinclusions, the process comprising the steps of: (a) preparing an aqueous thermoelectric oxide ceramic precursor solution; (b) forming a thermoelectric oxide ceramic precursor sol-gel mixture from the thermoelectric oxide ceramic precursor solution; (c) heating the thermoelectric oxide ceramic precursor sol-gel mixture to form a thermoelectric oxide ceramic precursor ash; (d) preparing a thermoelectric oxide ceramic precursor powder using the thermoelectric oxide ceramic precursor ash; (e) calcining thermoelectric oxide ceramic precursor powder, thereby forming a calcined thermoelectric oxide ceramic precursor powder; (f) preparing a thermoelectric oxide ceramic-nanoinclusion precursor by mixing the calcined thermoelectric oxide ceramic precursor powder with cerium oxide nanoparticles; (g) forming pellets of the thermoelectric oxide ceramic-nanoinclusion precursor; and (h) sintering the pellets of the thermoelectric oxide ceramic-nanoinclusion precursor, thereby forming the thermoelectric oxide ceramic material comprising nanoinclusions; wherein the aqueous thermoelectric oxide ceramic precursor solution comprises two or more thermoelectric oxide ceramic precursor salts; wherein the two or more thermoelectric oxide ceramic precursor salts comprise two or more metal cations corresponding to two or more metals in the thermoelectric oxide ceramic; wherein the forming the thermoelectric oxide ceramic precursor sol-gel mixture comprises mixing a sol-gel polymer and a sol-gel acid with the aqueous thermoelectric oxide ceramic precursor solution; and wherein the forming pellets of the thermoelectric oxide ceramic-nanoinclusion precursor comprises applying pressure to the thermoelectric oxide ceramic-nanoinclusion precursor.

Aspect 2. The process of Aspect 1, wherein the two or more thermoelectric oxide ceramic precursor salts comprise a calcium salt, a cobalt salt, and a bismuth salt.

Aspect 3. The process of Aspect 1 or Aspect 2, wherein the two or more thermoelectric oxide ceramic precursor salts comprise a nitrate anion.

Aspect 4. The process of any one of Aspect 1-Aspect 3, wherein the sol-gel polymer comprises polyethylene glycol.

Aspect 5. The process of any one of Aspect 1-Aspect 4, wherein the sol-gel acid is nitric acid.

Aspect 6. The process of any one of Aspect 1-Aspect 5, wherein the forming the thermoelectric oxide ceramic precursor sol-gel mixture further comprises mixing a sol-gel precursor with the aqueous thermoelectric oxide ceramic precursor solution.

Aspect 7. The process of Aspect 6, wherein the sol-gel precursor comprises ethylene glycol.

Aspect 8. The process of any one of Aspect 1-Aspect 7, wherein the heating the thermoelectric oxide ceramic precursor sol-gel mixture is carried out at a temperature from about 400° C. to about 600° C.

Aspect 9. The process of any one of Aspect 1-Aspect 8, wherein the calcining is carried out at a temperature of about 600° C. to about 800° C.

Aspect 10. The process of any one of Aspect 1-Aspect 9, wherein the forming pellets of the thermoelectric oxide ceramic-nanoinclusion precursor comprises applying uniaxial pressure; and where the pressure applied is about 0.5 GPa to about 2 GPa.

Aspect 11. The process of any one of Aspect 1-Aspect 10, wherein the sintering the pellets of the thermoelectric oxide ceramic-nanoinclusion precursor is carried out at about 850° C. to about 1100° C.

Aspect 12. A thermoelectric oxide ceramic composition prepared by the process of any one of Aspect 1 to Aspect 11.

Aspect 13. The composition of Aspect 12, wherein the composition comprises Ca₃₋ₓCeₓCo₄O_{9+δ}; and wherein x is about 0.05 to 0.45.

Aspect 14. The composition of any one of Aspect 12-Aspect 13, wherein the thermal conductivity is less than or equal to about 1.5 W/mK at 1073K.

Aspect 15. The composition of Aspect 12, wherein the composition comprises Ca₃Co₄O_{9+δ}Bi_{y} and CeOₓ; wherein y is about 0.01 to about 0.4; and wherein CeOₓ is present in an amount of about 1 wt % to about 5 wt % based on the total weight of CaₓCo₄O_{9+δ}Bi_{y} and CeO.

Aspect 16. The composition of Aspect 15, wherein the Figure of Merit ZT at 1073K is greater than or equal to about 1.0.

Aspect 17. The composition of Aspect 16, wherein the Figure of Merit ZT at 1073K is greater than or equal to about 1.1.

Aspect 18. The composition of Aspect 16, wherein the Figure of Merit ZT at 1073K is greater than or equal to about 1.2.

Aspect 19. The composition of Aspect 16, wherein the Figure of Merit ZT at 1073K is about 1.05 to about 1.30.

Aspect 20. The composition of any one of Aspect 15-Aspect 19, wherein the electrical power factor is about 1.5 mW/K²m to about 3 mW/K²m at 323K.

Aspect 21. The composition of any one of Aspect 15-Aspect 20, wherein the thermal conductivity is less than or equal to about 1.5 W/mK at 1073K.

Aspect 22. A thermoelectric oxide ceramic composition comprising CeO nanoinclusions.

Aspect 23. The composition of Aspect 22, wherein the composition comprises Ca₃₋ₓCeₓCo₄O_{9+δ}; and wherein x is about 0.1 to 0.5.

Aspect 24. The composition of Aspect 22, wherein the composition comprises Ca₃Co₄O_{9+δ}Bi_{y} and CeO; wherein y is about 0.01 to about 0.4; and wherein CeO is present in an amount of about 1 wt % to about 5 wt % based on the total weight of CaₓCo₄O_{9+δ}Bi_{y} and CeO.

Aspect 25. The composition of Aspect 24, wherein the Figure of Merit ZT at 1073K is greater than or equal to about 1.0.

Aspect 26. The composition of Aspect 25, wherein the Figure of Merit ZT at 1073K is greater than or equal to about 1.1.

Aspect 27. The composition of Aspect 25, wherein the Figure of Merit ZT at 1073K is greater than or equal to about 1.2.

Aspect 28. The composition of Aspect 25, wherein the Figure of Merit ZT at 1073K is about 1.05 to about 1.30.

Aspect 29. The composition of any one of Aspect 24-Aspect 28, wherein the electrical power factor is about 1.5 mW/K²m to about 3 mW/K²m at 323K.

Aspect 30. The composition of any one of Aspect 24-Aspect 29, wherein the thermal conductivity is less than or equal to about 1.5 W/mK at 1073K.

Aspect 31. A solid-state conversion device comprising a disclosed thermoelectric ceramic oxide composition of any one of Aspect 12-Aspect 30.

From the foregoing, it will be seen that aspects herein are well adapted to attain all the ends and objects hereinabove set forth together with other advantages which are obvious, and which are inherent to the structure.

While specific elements and steps are discussed in connection to one another, it is understood that any element and/or steps provided herein is contemplated as being combinable with any other elements and/or steps regardless of explicit provision of the same while still being within the scope provided herein.

It will be understood that certain features and subcombinations are of utility and may be employed without reference to other features and subcombinations. This is contemplated by and is within the scope of the claims.

Since many possible aspects may be made without departing from the scope thereof, it is to be understood that all matter herein set forth or shown in the accompanying drawings and detailed description is to be interpreted as illustrative and not in a limiting sense.

It is also to be understood that the terminology used herein is for the purpose of describing particular aspects only and is not intended to be limiting. The skilled artisan will recognize many variants and adaptations of the aspects described herein. These variants and adaptations are intended to be included in the teachings of this disclosure and to be encompassed by the claims herein.

Now having described the aspects of the present disclosure, in general, the following Examples describe some additional aspects of the present disclosure. While aspects of the present disclosure are described in connection with the following examples and the corresponding text and figures, there is no intent to limit aspects of the present disclosure to this description. On the contrary, the intent is to cover all alternatives, modifications, and equivalents included within the spirit and scope of the present disclosure.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary of the disclosure and are not intended to limit the scope of what the inventors regard as their disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### 1. Preparation of Doped Thermoelectric Ceramic Oxide Compositions Comprising Cerium Oxide Nanoinclusions

Ca₃₋ₓCeₓCo₄O_{9+δ} samples were prepared in which x=0, 0.05, 0.1, 0.15, 0.3, and 0.45 using sol-gel synthesis methods. Briefly, the precursor raw materials, i.e., Ca(NO₃)₂·4H₂O (99%, Acros Organics), Co(NO₃)₂·6H₂O (99%, Acros Organics), and Ce(NO₃)₃·6H₂O (99.5% Alfa Aesar), were mixed in the desired stoichiometric ratios in deionized water. Ethylene glycol (1:5 stoichiometry in relation to the nominal molar amounts of precursor materials) and polyethylene glycol were used to polymerize the solution. Nitric acid was added to induce nitrate salts decomposition and facilitate new compound formation. The solution was mechanically stirred at 353K for 3 hr and subsequently ashed at 773K for 2 hr in an air environment inside a box furnace. The ash material was manually ground, then ball-milled in a planetary ball milling machine with ethyl alcohol for 10 minutes. The dried powder was ground and calcined at 973K with oxygen flow in a tube furnace. The calcined powder was uniaxially pressed into pellets under the pressure of 1 GPa at room temperature. The pellets were sintered at 1233K for nine hours with controlled oxygen flow in a tube furnace.

Ca₃Co₄O_{9+δ}+Bi_{0.25} was prepared using chemical sol-gel methods to control the stoichiometry and uniform distribution of dopants. Briefly, the precursor raw materials, i.e., Ca(NO₃)₂·4H₂O (99%, Acros Organics), Co(NO₃)₂·6H₂O (99%, Acros Organics), and Bi(NO₃)₃·5H₂O (98%, Acros Organics), were mixed in the desired stoichiometric ratios in deionized water. Citric acid monohydrate (BDH Chemical), ethylene glycol, and polyethylene glycol were dissolved in the solution to polymerize the mixture. Nitric acid was included in the solution to promote sol-gel synthesis, nitrate salts decomposition, and the new compound formation. Similar to previous experimental samples, the sol-gel mixture was mechanically stirred at 353K for 3 h and subsequently ashed at 773K for 2 hr in an air environment inside a box furnace. The obtained ashes were ball-milled in ethyl alcohol in a stage with stainless steel balls and then dried at room temperature with a final manually ground stage after that to obtain uniform grain size in the powder. The reasonable homogeneous ashes were calcined at 973 K for four h in a tube furnace with constant oxygen flow. The polycrystalline ceramic powders were then incorporated with CeOₓ nanoparticles (CeO₂, 99.99%, US Research Nanomaterials, Inc.) with ˜10 nm in size. In order to achieve a uniform distribution of the CeOₓ nanomaterial and the calcined Ca₃Co₄O_{9+δ}+Bi_{0.25} powders, both materials were ball-milled together at low revolutions per minute to avoid damaging the crystal structure of the calcined Ca₃Co₄O_{9+δ}+Bi_{0.25} powders. The amount of CeOₓ nanoparticles studied was 2, 3, 4, 5, 6, and 8 wt %. The homogeneously mixed powders were uniaxially pressed into round pellets under a 1 GPa pressure at room temperature. The bulk samples were sintered at 1233K for nine hours in a tube furnace with constant oxygen flow and then cut into rectangular pellets to obtain the final desired sample for either the electrical or thermal measurements.

Both electrical transport properties and the thermal properties of the samples were measured along the direction parallel to the pressed plane of the pellets. The absolute Seebeck coefficient and electrical resistivity were measured using a Linseis LSR-1100 in a low-pressure helium (He) environment from 300K to 1073K. The thermal conductivity k was calculated using the following equation k=Δ·Cₚ·ρₘ where Cₚ, Δ, and ρₘ are the specific heat, thermal diffusivity, and mass density, respectively. The Cₚ and λ were measured from 373K to 1073K using a Linseis Laser Flash Analyzer 1200. The crystal phase of the samples was identified by PANalytical XPert-Pro XRD using Cu K-α radiation, 45 kV tension, and 40 mA current at room temperature. XRD patterns were collected on powder from sintered samples that were ground. The morphology of the pellets was examined using a Hitachi S-4700 SEM with EDS capabilities. The SEM images were processed using ImageJ software in order to measure several structural characteristics, such as porosity. TEM samples were prepared by mechanically polishing and subsequent ion milling in a liquid nitrogen-cooled holder. Electron diffraction, diffraction contrast, and high-resolution TEM imaging were performed in a JEOL JEM-2100 operated at 200 kV. The electron beam sampling dimension of EDS was about −20 nm under TEM imaging.

### 2. Characterization of Ca₃₋ₓCeₓCo₄O_{9+δ} Thermoelectric Oxide Ceramic Materials

The increase of the Ce doping level resulted in the increase of the bulk sample density for the various Ca₃₋ₓCeₓCo₄O_{9+δ} materials prepared as described above (see Table 1 below). The table provides apparent and relative densities of the samples Ca₃₋ₓCeₓCo₄O_{9+δ} with x=0, 0.05, 0.1, 0.15, 0.3, 0.45 and cobalt oxide sample.

TABLE 1

| | | | | Relative Density | Relative Density | Relative Density |
|---|---|---|---|---|---|---|
| | | Apparent | Calculated* Density | to single crystal | to single crystal | to single crystal |
| | | Density | for Single Crystal | Ca₃Co₄O₉ (%) | Ca₃Co₄O₉ (%) | Ca₃₊ₓCo₄O₉ (%) |
| Sample | | (g/cm³) | (g/cm3) | (A.C. Masset) | Calculated | Calculated |
| Ce (x) | 0 | 3.829 | 4.66 | 82 | 82 | 82 |
| | 0.05 | 3.952 | 4.71 | 84 | 85 | 84 |
| | 0.1 | 3.934 | 4.76 | 84 | 84 | 83 |
| | 0.15 | 3.893 | 4.81 | 83 | 84 | 81 |
| | 0.3 | 4.093 | 4.92 | 87 | 88 | 83 |
| | 0.45 | 4.278 | 5.09 | 91 | 92 | 84 |

| Single crystal CCO (A.C. Masset) | | 4.68 | 100 | 100 | 100 |
|---|---|---|---|---|---|
| Cobalt Oxide | 4.51 | | | | |

*Using XRD lattice paramenters and superlatice model with 10-11 unit cells with b = Bb1 = 13b2 (A.C. Masset)

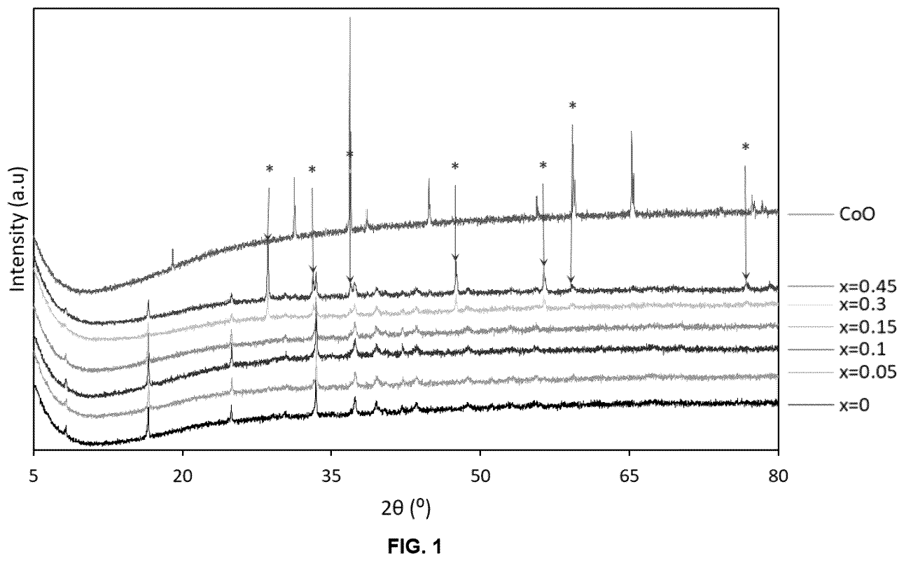

With reference to FIG. 1, the XRD data show that peaks from Ca₃Co₄O_{9+δ} phase with the monoclinic structure were dominant and indexed for all samples of this Example, while samples x=0.15-0.45 show the additional peaks associated with CeOₓ and CoOₓ. As summarized in Table 2, there are systematic lattice parameter changes induced by the Ce doping of Ca₃Co₄O_{9+δ}. For the samples with 0≤x≤0.1, a and b₁ increase while b₂ keeps constant. For the samples with 0.3≤x≤0.45, there is no difference in b₁, while b₂ keeps increasing slightly for samples with 0.15≤x≤0.45.

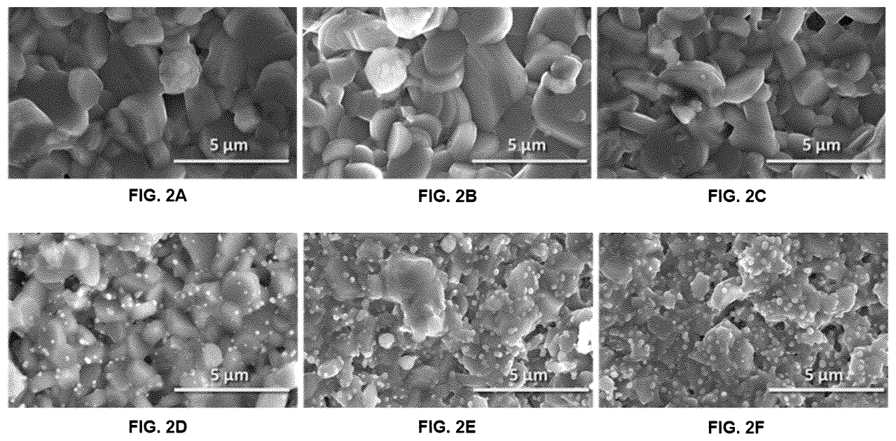

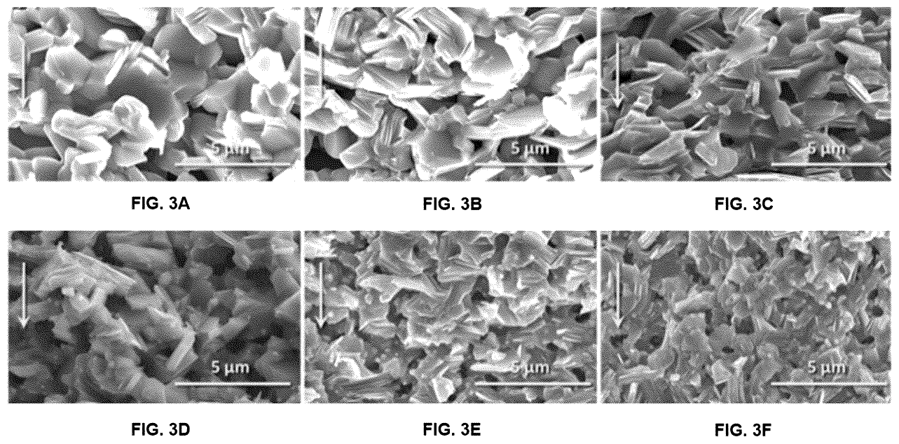

With reference to, and as shown in, FIG. 2 and FIG. 3, both the surface plan-view and the fractured cross-section of the pellets are imaged under SEM. All samples present the plate-shaped grains, and there is no apparent preferred crystal alignment, or the crystal texture shown in the samples. The baseline sample is with the larger dimension of the grains of ˜3.5 μm, and there is a slight tendency of the decreased grain size for the samples with increased Ce concentration. There is a formation of nanoparticles for all samples with the Ce doping level of x>0.1. Noteworthy, the nanoparticles keep constant dimensions of 100 nm, while the particle density increase with the increase of Ce doping level for Ca₃₋ₓCeₓCo₄O_{9+δ} samples of 0.15≤x≤0.45. Using ImageJ software, the porosity and volume ratio between nanoparticles and Ca₃₋ₓCeₓCo₄O_{9+δ} grains were determined and the data are shown in Table 3, which provides data for the porosity and volume ratio of Ca₃Co₄O_{9+δ} (CCO) doped grains/nanoparticles (NP) for both surface and cross-section SEM views

TABLE 2

| Ca₃₋ₓCeₓCo₄O₉ | x = 0 | x = 0.05 | x = 0.1 | x = 0.15 | x = 0.3 | x = 0.45 |
|---|---|---|---|---|---|---|
| a (Å) | 4.843 | 4.855 | 4.855 | 4.847 | 4.850 | 4.853 |
| b₁(Å) | 4.557 | 4.559 | 4.561 | 4.563 | 4.566 | 4.566 |
| b₂(Å) | 2.792 | 2.792 | 2.792 | 2.799 | 2.800 | 2.801 |
| c(Å) | 10.821 | 10.800 | 10.814 | 10.820 | 10.812 | 10.812 |
| β(°) | 98.248 | 98.294 | 98.391 | 98.204 | 98.319 | 98.328 |
| b₂/b₁ | 0.613 | 0.612 | 0.612 | 0.613 | 0.613 | 0.613 |

TABLE 3

| Chemistry | Ce0.15 | Ce0.3 | Ce0.45 |
|---|---|---|---|
| Porosity (%) - Surface | 2.39 | 5.08 | 6.17 |
| Porosity (%) - Cross-section | 6.18 | 5.64 | 8.95 |
| Vol/ratio CCO/Nanoparticles - Surface | 39.08 | 18.66 | 14.17 |
| Vol/ratio CCO/Nanoparticles - Cross-section | 91.44 | 61.71 | 43.27 |

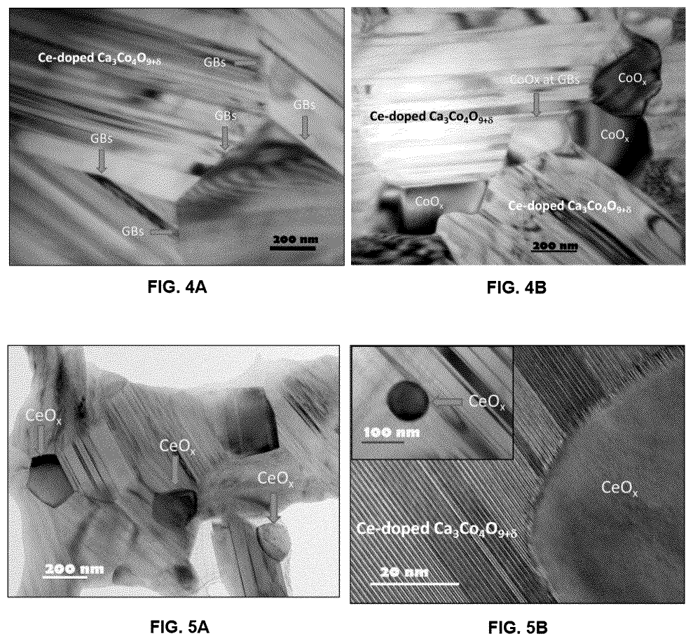

Intragranular saturation of Ce in Ca₃Co₄O_{9+δ} and the resultant precipitation of CeOₓ was determined using TEM analysis from the samples, Ca_{2.9}Ce_{0.1}Co₄O_{9+δ} and Ca_{2.55}Ce_{0.45}Co₄O_{9+δ}, respectively. With reference to FIG. 4, the Ce-doped grains appeared to be homogenous with the typical nano-lamella (Ref. 29), and there is no evidence of the intragranular precipitation from the samples with the designed chemistry of Ca_{2.9}Ce_{0.1}Co₄O_{9+δ}. Most of the grain boundaries (GBs) are free of precipitates. There is the formation of the CoOₓ, at some grain boundaries. The precipitates at the grain boundaries are pure CoOₓ and free of Ca or Ce.

The Ca_{2.55}Ce_{0.45}Co₄O_{9+δ} samples presented a small number of additional phases of CaO and CoOₓ nanoparticles, mainly extruding on the internal surface of the pores. For the Ca_{2.55}Ce_{0.45}Co₄O_{9+δ} samples with a higher Ce substitution level, the Ce/Ca ratio remained to that of the Ca_{2.9}Ce_{0.1}Co₄O_{9+δ}. Meanwhile, there are CeOₓ, with the dimension of about 100 nm, presented at the three different locations of extruding at the internal surface of the porosity, intergranular and intragranular precipitates. There is no cation intermixing among the COOₓ, CaO, and CeOₓ. In the region that does not overlap with the Ca_{2.9}Ce_{0.1}Co₄O_{9+δ} matrix, the EDX taken from CeO, is without Co or Ca. The intragranular precipitates within the grains present spherical morphology, indicating the interface energy-dominated formation. Moreover, the pure nano precipitates had the semi-coherent crystal interface with the Ce-doped grain matrix and one set of the crystal plane parallel to that Ca₃Co₄O_{9+δ} grain.

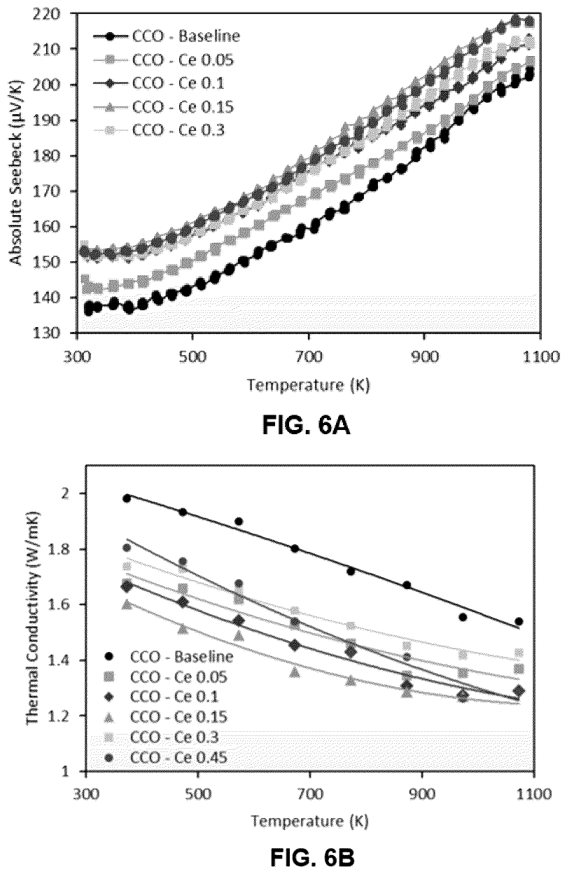

With reference to FIG. 6, the Seebeck coefficient of Ca₃₋ₓCeₓCo₄O_{9+δ} samples as a function of temperature is shown in FIG. 6(a) from around 320K up to 1073K. Up to doping level x=0.1, the Seebeck coefficient, especially at a low temperature of about 373K, increased with Ce doping levels and appeared to be 137.82 μV/K for x=0, of 143.3 μV/K for x=0.05, and of 151.71 μV/K for x=0.1. At a higher doping level of x=0.15 to x=0.45, the Seebeck coefficient of the samples with different doping levels is about constant at 153.86 μV/K at 373K. At 373K, the lowest resistivity for the baseline sample was 40.36 μΩm, for Ca_{2.95}Ce_{0.05}Co₄O_{9+δ}: 66.86 μΩm, for Ca_{2.9}Ce_{0.1}Co₄O_{9+δ}: 75.97 μΩm, and for Ca_{2.55}Ce_{0.45}Co₄O_{9+δ} 171.25 μΩm. For Ca₃₋ₓCeₓCo₄O_{9+δ} samples with doping level x up to 0.1, the samples presented metallic transport behavior and the electrical resistivity increased with temperature and the doping level. As the doping level of Ca₃₋ₓCeₓCo₄O_{9+δ} samples over 0.1, the electrical resistivity dramatically increased with the doping level.

FIG. 6 also shows the thermal conductivities of the cerium doped samples. At 373K, there was a continuous decrease of the thermal conductivity for doping level up to 0.15. Ca_{2.85}Ce_{0.15}Co₄O_{9+δ} has the lowest thermal conductivity of 1.604 W/mK at 373K. When the doping level was over 0.15, with the increase of the Ce doping level, the thermal conductivity increased, and Ca_{2.55}Ce_{0.45}Co₄O_{9+δ} had the highest at 1.805 W/mK. All the samples present the decrease of the thermal conductivity with the increase of temperature.

### 3. Characterization of the Effect of Ce Substitution on the Unit Cell of the Misfit-Layered Oxide

In order to assess the effect of Ce substitution of Ca on nano-precipitation, TEM studies were carried out. The TEM results clearly indicated that CeOₓ precipitates are pristine and without any Ca and Co incorporating into the lattice. Without wishing to be bound by a particular theory, it is believed that the CeOₓ is formed through solid-state precipitation. With reference to FIG. 5, the atomic resolution images show there is a preferred orientation relationship with the matrix and the atomic scale binding without any cracking at the interface.

The nano-precipitates were present in the samples with the Ce concentration higher than 0.1. There were systematic lattice parameter changes when the doping level was lower than 0.1. The incommensurate Ca₃Co₄O₉ was misfit-layered consisting of two monoclinic subsystems with identical a, c, and β parameters but different b parameters. Along the c axis of Ca₃Co₄O₉ unit cell, there was stacking of triple rock salt-type layers Ca₂CoO₃ of the first subsystem for b₁ and single Cdl₂-type CoO₂ layers of the second subsystem for b₂ (Ref. 26). For the samples with the designed chemistry of Ca₃₋ₓCeₓCo₄O_{9+δ}, the unchanged b₂ lattice parameter in the x<0.1 samples indicated the CoO₂ layer was not disturbed. Meanwhile, a and b₁ kept increasing gradually and slightly, revealing the substitution of larger Ce³⁺ (Ce³⁺ of 115 pm) rather than smaller Ce⁴⁺ (Ce⁴⁺ of 101 pm) to replace the Ca²⁺ (Ce²⁺ of 114 pm) in the Ca₂CoO₃ subsystems. For the sample of Ca_{2.9}Ce_{0.1}Co₄O_{9+δ}, TEM results showed that the Ce doping level in the grain interior is in agreement with that from the designed chemistry of Ca_{2.9}Ce_{0.1}Co₄O_{9+δ}, corresponding to the Ce/Ca ratio of 3.5% in the CCO lattice. Interestingly, the sample Ca_{2.55}Ce_{0.45}Co₄O_{9+δ} also has the same Ce/Ca ratio of 3.5%, indicating the possible saturation level of Ce is about 3.5%.

Under the solubility limit of x=0.1, the continuous changes of the Ce³⁺ replacing Ca²⁺ will possibly result in the formation of the oxygen vacancies and further expelling of Co cations from the Ca₂CoO₃ subsystems that is evidenced by the formation of the small amount of CoOₓ precipitates at the grain boundaries. There is no Ce within the CoOₓ. Probably due to the significant ionic radius difference between Ce and Co ions, Ce presumably did not replace the Co within either Ca₂CoO₃ or the CoOₓ subsystems.

When the saturation limit of Ce/Ca of 3% was reached, there was the appearance of nanoparticles as shown in SEM from the samples with Ce doping x>0.1. Moreover, the size of the particles remains constant, and the density increased with the increase of doping. For the Ca₃₋ₓCeₓCo₄O_{9+δ}, when the amount Ce is over the saturation alloying limit of Ce=0.1, a further increase of the Ce doping level caused a deficiency of cations in the Ca sites. This could be associated with the formation of Co⁴⁺ to Co³⁺ that appears to be evidenced by the slight but continuous increase of the b₂ lattice parameters, resulting in the formation of both CaOₓ and CoOₓ, as seen in the TEM images. In other words, when it is over the solubility limit, the metastable solid solution of Ce imparts a crystal structure of the Ca₃₋ₓCeₓCo₄O_{9+δ} that undergoes the decomposition and formation of the secondary phases of including the CaO, CoOₓ, and CeOₓ.

### 4. Characterization of the Effect of Ce Substitution on the Electrical Properties, Thermal Conductivities, and ZT of Misfit Layered Oxide Ceramics

The above analysis on the crystal structure changes induced by Ce substitution appeared to be consistent with the electrical performance for samples of different chemistry. For example, in the sample Ca₃₋ₓCeₓCo₄O_{9+δ} when is X≤0.1, the Seebeck coefficient, especially the room temperature, increased. Without wishing to be bound by a particular theory, it is believed this was due to the Ce³⁺ is replacing the Ca²⁺. Similar to the increased Seebeck coefficient increase induced by Bi³⁺ substitution of the Ca²⁺, it is believed that Ce³⁺ substitution for Ca introduces negative charge carriers, reduces carrier concentration, and increase the Seebeck coefficient. Without wishing to be bound by a particular theory, the high oxidation state of rare-earth elements Ce and the reduced electrical carrier concentration also increase electrical resistivity. Further, without wishing to be bound by a particular theory, it is believed that CoOₓ formations, especially those at the grain boundaries, can increase the electrical resistivity and decrease the thermal conductivity.

The data show that the Seebeck coefficient is constant for the samples with higher doping levels from x=0.1 to x=0.45 and appears to be consistent with the saturation of Ce inside the Ca₃₋ₓCeₓCo₄O_{9+δ} lattice. When the doping level is over the saturation limit of x=0.1, the further exsolution of the CoOₓ and CaOₓ does not appear to affect the Seebeck coefficient. When the Ce was increased to 0.15, the disturbance in the CoOₓ subsystems that is reflected in the increase of the b₂ lattice parameter caused a large increase in the electrical resistivity. On the other hand, for the Ca₃₋ₓCeₓCo₄O_{9+δ} 0.1≤x≤0.45, the formation of CeOₓ further increases the electrical resistivity due to the formation of the CeOₓ, especially those at the grain boundaries.

For the samples with Ce<0.1, except for the small amount of CoOₓ at the grain boundaries, the entire sample is an isostructural solid solution that features atomic mass fluctuation in the crystal lattice. Atomic-scale defects in alloys scatter phonons due to differences in mass, and substitution of Ca by the higher atomic number Ce could lead to significantly lower thermal conductivity. Due to the Ce substitution in the Ca and the presence of nano-lamella inside the Ca₃Co₄O_{9+δ} grains, the short-wavelength phonons are effectively scattered in alloys, but the mid-to-long wavelength phonons can propagate without significant scattering and thereby still contribute to heat conduction. By the inclusion of nanoparticles, a substantial reduction in lattice thermal conductivity can be achieved by the additional scattering of mid- and long-wavelength phonons by the nanoparticles. Nevertheless, for the ceramics with the stoichiometric substitution and the designed chemistry of Ca₃₋ₓCeₓCo₄O_{9+δ} 0.1≤x≤ 0.45, the benefit of the decreased thermal conductivity to the overall ZT has largely diminished due to the increases in the electrical resistivity due to the formation of the CeOₓ, especially those at the grain boundaries, and the related stoichiometric changes inside the Ca₃Co₄O_{9+δ} lattices.

The foregoing data show a solubility limit of the Ce in the Ca₃₋ₓCeₓCo₄O_{9+δ} 0.1≤x≤0.45 with the formation of the thermodynamically stable CeOₓ precipitates.

### 5. Characterization of the Crystal Changes Associated with CeOₓ as Nano-Inclusions Nanoparticle Diffusion into Bi-Doped Misfit Layered Oxide Matrix

The foregoing data obtained for the Ca₃₋ₓCeₓCo₄O_{9+δ} thermoelectric oxide ceramic materials demonstrate that the precipitation of the CeOₓ and introducing the CeOₓ as nano-inclusions can be accomplished without deteriorating the integrity stoichiometry of pristine and doped Ca₃Co₄O_{9+δ} to further increase its Seebeck coefficient and decrease its thermal conductivity. To assess further effects on overall ZT that may be associated with incorporation of such CeOₓ nano-inclusions, powders with CeOₓ nano-particles were mixed with the powders of Ca₃Co₄O_{9+δ}Bix with Bi non-stoichiometric addition were prepared as described and characterized. Previous reports (Ref. 30) suggested that the introduction of the non-stoichiometric addition of Bi into the Ca₃Co₄O_{9+δ} can achieve a ZT performance up to 0.91 when utilized simultaneously with rare earth element Tb. The present example utilizes Ca₃Co₄O_{9+δ}Bi_{0.25} as the parent material to analyze the effect of different weight percentage (wt %) incorporation of CeOₓ rare-earth nanoparticles oxides.

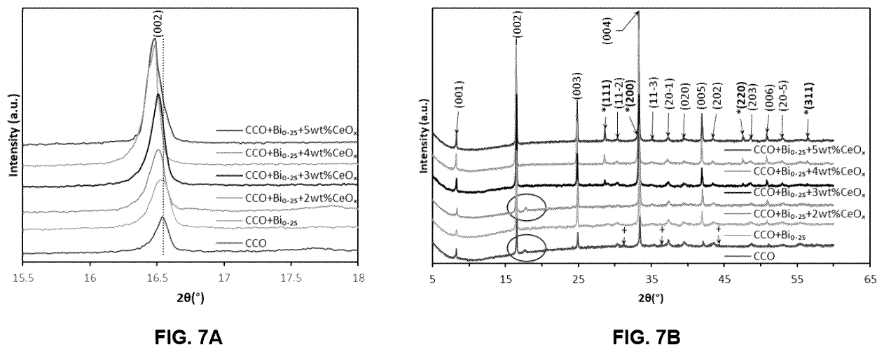

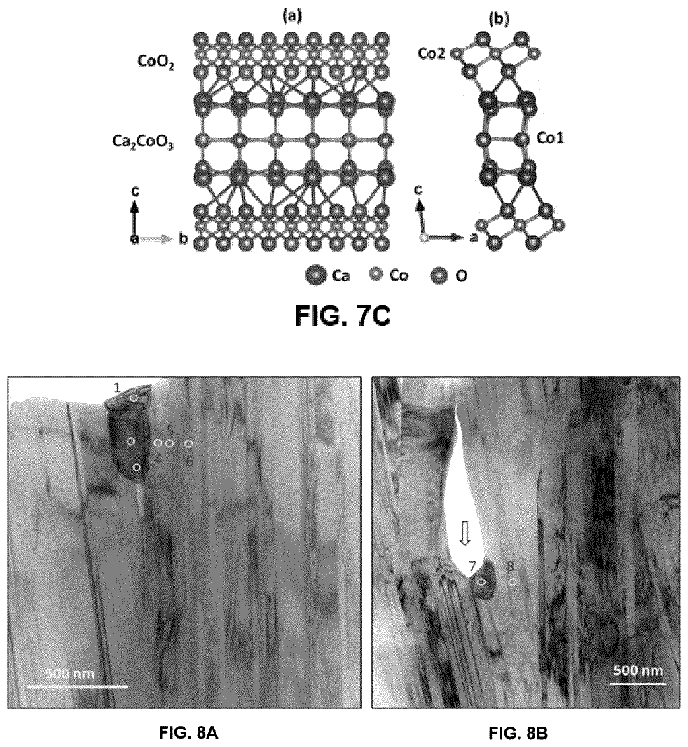

The XRD peaks from the samples with Bi non-stoichiometric addition and simultaneous CeOₓ nanoparticle addition into Ca₃Co₄O_{9+δ} are shown in FIG. 7. The characteristic peaks from the monoclinic symmetry phase were identified for the Ca₃Co₄O_{9+δ}Bi_{0.25}+wt % CeOₓ samples. The commonly secondary phase Co₃O₄ is observed in a minor amount for the baseline Ca₃Co₄O₉+o. Notwithstanding, the Bi-doped samples do not show Co₃O₄ impurity phase on the diffraction spectrum with the CeOₓ concentrations up to 5 wt %. Moreover, the incorporation of the CeOₓ nanoparticles into the Bi-doped Ca₃Co₄O_{9+δ} matrix results in the appearance of the characteristic diffraction peaks of the Ce₀₂ material with a cubic crystal structure. Furthermore, diffraction peaks shift to lower Bragg's angle after the doping of Bi and incorporation of CeOₓ nanoparticles into the layered oxide materials. The shift of the diffraction peaks indicates a change of lattice parameters affected by both the Bi doping and Ce diffusion from the nanoparticles. The calculated lattice parameters for the samples are listed in Table 4 below.

TABLE 4

| | a | b₁ | b₂ | c | β |
|---|---|---|---|---|---|
| Chemistry | (Å) | (Å) | (Å) | (Å) | (°) |
| CCO | 4.851 | 4.570 | 2.785 | 10.839 | 98.521 |
| CCO + Bi_{0.25} | 4.853 | 4.576 | 2.789 | 10.844 | 98.295 |
| CCO + Bi_{0.25} + 2 wt % CeOx | 4.854 | 4.577 | 2.792 | 10.855 | 98.310 |
| CCO + Bi_{0.25} + 3 wt % CeOx | 4.858 | 4.577 | 2.791 | 10.869 | 98.412 |
| CCO + Bi_{0.25} + 4 wt % CeOx | 4.868 | 4.577 | 2.790 | 10.874 | 98.579 |
| CCO + Bi_{0.25} + 5 wt % CeOx | 4.868 | 4.577 | 2.789 | 10.872 | 98.533 |

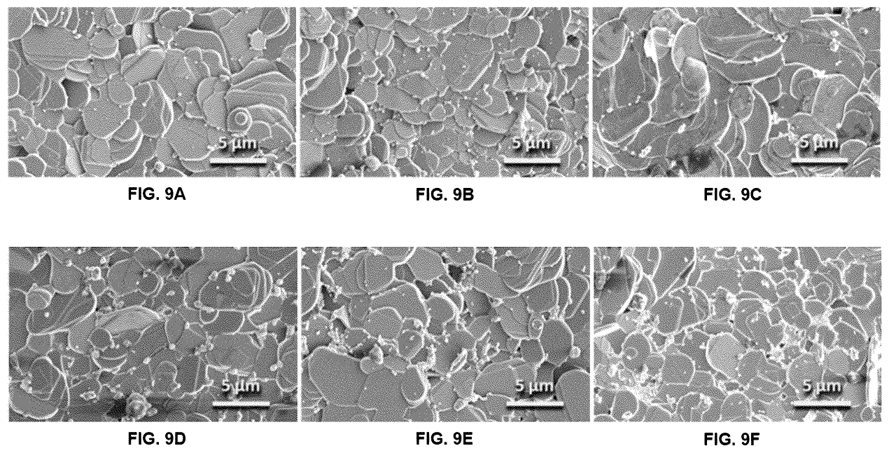

TEM and EDS analysis were performed on the Ca₃Co₄O_{9+δ}Bi_{0.25+3} wt % CeOₓ polycrystalline material to further explore the complex inward and outward diffusion of Ca, Co, Bi, Ce, and O atoms in the Ca₃Co₄O_{9+δ}Bi_{0.25}+wt % CeOₓ samples. FIG. 8A-8B shows the nanostructure on the grain boundaries and grain interior of Ca₃Co₄O_{9+δ} and the morphology of CeOₓ nanoparticles. The image data in FIGS. 8A-8B indicate that CeOₓ nanoparticles have a size ˜100-200 nm. The images in FIGS. 8A-8B indicate regions 1-8 that were sampled for EDS analysis shown in Table 5.

TABLE 5

| At % | O | Ca | Co | Bi | Ce |
|---|---|---|---|---|---|
| 1 | 63.4 | 0.78 | 2.27 | | 33.52 |
| 2 | 59.5 | 0.72 | 2.23 | | 37.54 |
| 3 | 61 | 0.90 | 2.56 | | 35.55 |
| 4 | 54.4 | 20.07 | 22.69 | 2.16 | 0.73 |
| 5 | 56.1 | 19.23 | 22.46 | 1.98 | 0.26 |
| 6 | 57 | 18.73 | 22.16 | 1.91 | 0.25 |
| 7 | 65.77 | 0.70 | 1.97 | | 31.56 |
| 8 | 61.33 | 17.08 | 19.58 | 1.75 | 0.26 |

The Ce incorporation inside the Ca₃Co₄O_{9+δ} lattice was confirmed with the TEM analysis. Without wishing to be bound by a particular theory, it is believed that the TEM data further suggests that there is a higher Ce concentration close to the CeOₓ nanoparticle (confirming the increasing inward diffusion of Ce into the Ca₃Co₄O_{9+δ} lattice with the increasing CeO, nanoparticle concentration). Additionally, TEM results were consistent with XRD results revealing the unaltered Ca₃Co₄O_{9+δ} and CeOₓ phases (there is no additional phase induced by the interaction of the Ca₃Co₄O_{9+δ} matrix with the nanoparticles). Bi non-stoichiometric addition into the Ca₃Co₄O_{9+δ} results in the Bi presence inside the grain interior and in the grain boundaries. The results are consistent with the previously reported results on incorporating oversized dopants K (Ref. 31), Ba (Ref. 29), and Bi (Ref. 20), showing the intergranular location in Ca₃Co₄O_{9+δ} boundaries attract oversized dopants while depleting the undersized dopants.

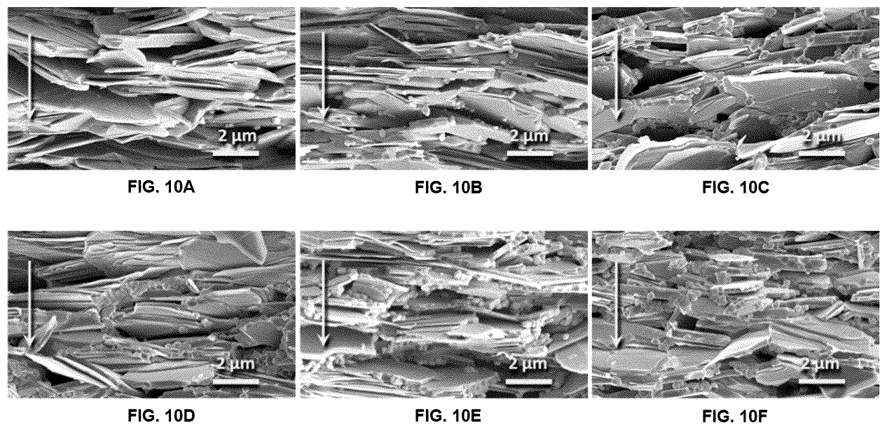

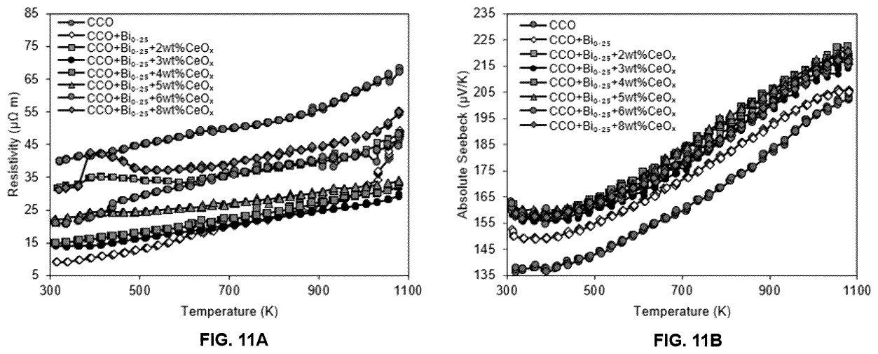

SEM images of Ca₃Co₄O_{9+δ}Bi_{0.25} with varied wt % CeOₓ samples after the sintering stage are shown in FIG. 9 and FIG. 10 for the images from the top surface and the cross-sectional images from the fractured internal surface of the pellets. The arrow in each cross-sectional SEM image indicates the pressing direction of the pellet. The Ca₃Co₄O_{9+δ} samples that were analyzed show large anisotropy with micron-sized plate-shaped grains having a larger dimension in direction to the a-b plane of the monoclinic Ca₃Co₄O₉, which is consistent with the results for Bi-doped Ca₃Co₄O_{9+δ} materials. It was previously reported (Ref. 29) that when Bi has doped into the Ca₃Co₄O_{9+δ}, the size of the crystals gradually increases parallel to the a-b plane of the elongated crystal grains while remaining with an equivalent size in the c-axes, producing the development of the crystal texture that preferentially aligns the crystal grain orientation. It is assumed that Bi at the grain boundary decreases the grain boundary energy and that influences the grain rotation, which is mainly driven by the dependence of the grain boundary energy (Ref. 32). On the other hand, the size and orientation alignment are not disturbed with the different concentrations of the CeOₓ nanoparticles. Samples are observed to have Ca₃Co₄O_{9+δ} grains with similar size and orientation between different concentrations. The CeOₓ preference appears to be localized in the grain boundaries of the Ca₃Co₄O_{9+δ} grains. Samples with 2 and 3 wt % of CeOₓ show nanoparticles dispersed throughout the bulk ceramic (although more inclined to be deposited in the grain boundary as discussed), but there is a clear agglomeration of the CeOₓ nanoparticles at concentrations at 4 wt % and above. The agglomeration of CeOₓ could hinder the carrier mobility of neighboring grains due to the lower electronic properties of the nanoparticles. Moreover, the agglomeration of the nanoparticles also results in an increase in the particle size, which is not the case for the dispersed CeOₓ nanoparticles at 2 and 3 wt %.

### 6. Characterization of the Electrical and Thermal Properties Associated with CeOₓ as Nano-Inclusions Nanoparticle Diffusion into Bi-Doped Misfit Layered Oxide Matrix

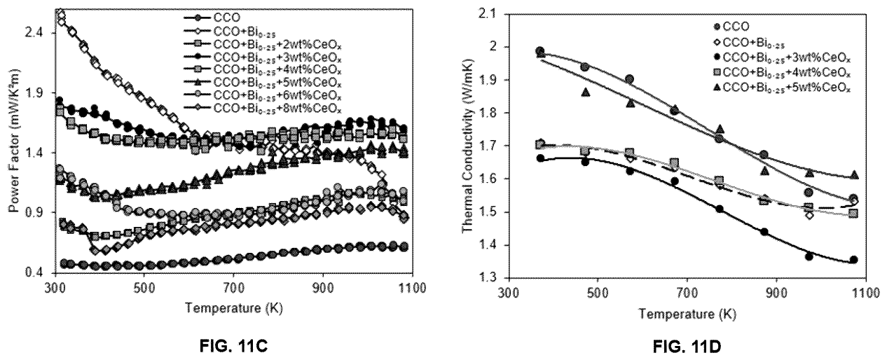

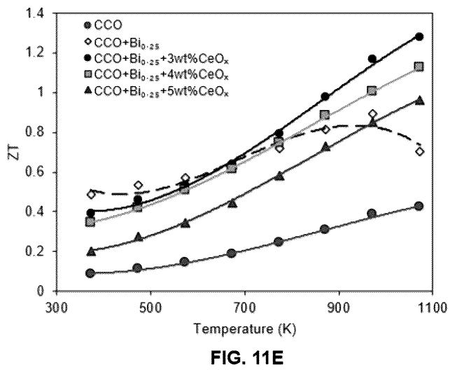

The temperature dependence of the electrical properties is shown in FIG. 11 (A) ρ-T, (B)S-T, and (C) S²/ρ-T for different Ca₃Co₄O_{9+δ}Bi_{0.25}+wt % CeOₓ samples. The ρ-T properties of the samples show mostly a metallic-like behavior, and the ρ increases as the temperature increases. The baseline Ca₃Co₄O_{9+δ} sample has ρ value ˜39.9 μΩm and ˜68.4 μΩm at 323K and 1073K, respectively. With the incorporation of Bi as non-stoichiometric doping into the Ca₃Co₄O_{9+δ}, the ρ value decreases considerably to ˜9.1 μΩm at 323K, which represents a 77% decrease in electrical resistance compared to the baseline Ca₃Co₄O_{9+δ}. However, the Ca₃Co₄O_{9+δ}Bi_{0.25} sample shows a less pronounced improvement of the electrical resistivity at 1073K, reaching a value of 49.5 μΩm, representing only a 27% reduction at high temperature compared to the values obtained for the pristine material. While the addition of CeOₓ nanoparticles with 2 wt % incorporation into the Ca₃Co₄O_{9+δ} matrix does not improve the performance of the Ca₃Co₄O_{9+δ}Bi_{0.25} samples initially but a further increase of CeOₓ concentration (for wt % concentrations of 3, 4, and 5) shows a significant effect on the electrical properties of the layered misfit material, particularly at high temperature. The incorporation of 3 wt % of CeOₓ nanoparticles produces the most notorious reduction in electrical resistivity at high temperatures. It is suggested that the inclusion of CeOₓ nanoparticles and Ce inward diffusion into the Ca₃Co₄O_{9+δ} lattice help the matrix to become more stable at higher temperatures. The optimal sample with 3 wt % of CeOₓ incorporated into the Bi-doped Ca₃Co₄O_{9+δ} displays a ρ value of ˜14.0 μΩm at 323K, and while it is slightly higher than the Ca₃Co₄O_{9+δ}Bi_{0.25} without the nanoparticles, it is still a 65% decrease in electrical resistance compared to the pristine Ca₃Co₄O_{9+δ}. More importantly, the sample with chemistry Ca₃Co₄O_{9+δ}Bi_{0.25+3} wt % of CeOₓ shows low ρ at 1073K, reaching a value of 29.1 μΩm, representing a 58% reduction compared to the pristine material and a 41% further reduction compared to the Bi-doped Ca₃Co₄O_{9+δ}Bi_{0.25} at high-temperature. This suggests that the appropriate amount of 3 wt % of CeOₓ nanoparticles do not disturb the carrier mobility of the misfit layered material and further boost the electrical properties compared to the Ca₃Co₄O_{9+δ}Bi_{0.25} material without the nanoparticles. The low ρ in the Ca₃Co₄O_{9+δ}Bi_{0.25} crystalline samples could be attributed to the improved grain alignment of the materials even after the CeOₓ nanoparticle incorporation shown in the SEM images. The increase in p at high concentrations of CeOₓ nanoparticles (5, 6, and 8 wt %) could be associated by the agglomeration of CeOₓ blocking the carrier mobility within the neighboring Ca₃Co₄O_{9+δ} grains, while the increased p at 2 wt % of CeOₓ nanoparticles could be attributed to some level of non-optimal doping in the Ca₃Co₄O_{9+δ}Bi_{0.25}Ceₓ (Ce diffuse into the Ca₃Co₄O_{9+δ} lattice while there is also a pronounce Ca and Co outward diffusion).

Moreover, the doping of Bi and further incorporation of CeOₓ nanoparticles have a simultaneous influence on the Seebeck coefficient. The pristine Ca₃Co₄O_{9+δ} sample displays a Seebeck coefficient value of 135.9 μV/K at 323 K and 202.5 μV/K at 1073K. Bi doping the misfit layered material to the chemistry of Ca₃Co₄O_{9+δ}Bi_{0.25} increases the magnitude of the S in the whole range of temperatures analyzed. The Bi-doped Ca₃Co₄O₉ ceramics achieve values of 150 μV/K at 323K, which represents a 10% increase compared to the pristine material and a more modest improvement of 1.5% at high-temperature (205.7 μV/K at 1073K obtained for the Ca₃Co₄O_{9+δ}Bi_{0.25} ceramics). The improvement of the Seebeck coefficient could be attributed to the previously reported energy filtering effect of the segregated Bi atoms at the grain boundaries of the Ca₃Co₄O_{9+δ} grains. Remarkably, with the incorporation of the CeOₓ nanoparticles into the Ca₃Co₄O₉Bi_{0.25}, not only the ρ values were lowered at high temperatures, but also the S values were improved at low temperatures and conserved the significant improvement of S at high-temperature in comparison to the pristine Ca₃Co₄O₉ and the Ca₃Co₄O₉Bi_{0.25}. The Bi-doped Ca₃Co₄O₉ ceramics with incorporated nanoparticles achieve values of ˜160 μV/K at 323K, which represents a 17% increase compared to the pristine material and an of 6.6% at high-temperature (˜216 μV/K at 1073K obtained for the Ca₃Co₄O_{9+δ}Bi_{0.25} ceramics). Some reports suggest that nanoparticles could also serve as energy filtering layers to improve the Seebeck coefficient (by means of reduction of carrier concentration; see Ref. 33) given the preferred agglomeration of the CeOₓ nanoparticles in the grain boundaries of the Ca₃Co₄O_{9+δ} grains, energy filtering effect by the associated CeOₓ nanoparticles at the grain boundary cannot be discarded. Notwithstanding, the inward diffusion (into the Ca₃Co₄O_{9+δ} lattice) of the Ce³⁺/Ce⁴⁺ replacing the outward diffusion of Ca^{t}+(into the crystal lattice of CeOₓ) represents a more significant influence in the carrier concentration of the Ca₃Co₄O_{9+δ} ceramic.

The reduction of the electrical resistivity with a simultaneous increase in the Seebeck coefficient for the Ca₃Co₄O_{9+δ}Bi_{0.25}+wt % CeOₓ samples results in a drastic improvement of the electrical PF(S²/ρ). The pristine Ca₃Co₄O_{9+δ} sample has a PF value of ˜0.47 mW/K²m and ˜0.60 mW/K²m at 323 K and 1073K, respectively. Whereas the Ca₃Co₄O_{9+δ}Bi_{0.25} displays an electrical PF value of ˜2.57 mW/K²m at 323 K, which represents an increase of 5.46 times compared to the pristine material and an electrical PF value of ˜0.86 mW/K²m at 1073K, representing a modest 43% improvement compared to the undoped Ca₃Co₄O_{9+δ} ceramic. On the other hand, the sample with chemistry Ca₃Co₄O_{9+δ}Bi_{0.25+3} wt % of CeOₓ shows an electrical PF value of ˜1.84 mW/K²m at 323 K, which represents an increase of 3.91 times compared to the pristine material but slightly lower values than that of the Ca₃Co₄O_{9+δ}Bi_{0.25} without nanoparticles. The key improvement of the Ca₃Co₄O_{9+δ}Bi_{0.25+3} wt % of CeOₓ comes at a higher temperature where the electrical PF achieves a value of ˜1.6 mW/K²m at 1073K, which translates to an improvement of 2.67 times compared to the value of the pristine Ca₃Co₄O_{9+δ} ceramic and almost twice the value of the Ca₃Co₄O_{9+δ}Bi_{0.25} without nanoparticles. Therefore, the optimal concentration of CeOₓ nanoparticles induces a drastic improvement of the electronic transport properties over the whole analyzed temperature.

The temperature dependence on the thermal properties and the Figure of Merit ZT of the ceramics analyzed are shown in FIG. 11 (D) K-T, and (E) ZT for different Ca₃Co₄O_{9+δ}Bi_{0.25}+wt % CeOₓ samples. The baseline Ca₃Co₄O_{9+δ} sample has thermal conductivity values of ˜1.98 W/mK and ˜1.54 W/mK at 323 K and 1073K, respectively. Consistent with previous reports (Ref. 29), the incorporation of the heavier atom Bi as a doping element into the Ca₃Co₄O_{9+δ}, the thermal conductivity values decrease to ˜1.71 W/mK at 323 K, which represents a 13.7% decrease in the thermal conductivity values compared to the undoped Ca₃Co₄O_{9+δ}. The thermal conductivity value at 1073K for the Bi-doped Ca₃Co₄O_{9+δ} is 1.53 W/mK, which represents almost the same values as that of the undoped material. For the samples with chemistry Ca₃Co₄O_{9+δ}Bi_{0.25} and different concentrations of CeOₓ nanoparticles, the thermal conductivity changes drastically. The thermal conductivity measurements were performed in the concentrations with the most improved electronic properties. The samples with Ca₃Co₄O_{9+δ}Bi_{0.25} and 3, 4, and 5 wt % of CeOₓ nanoparticles were analyzed. It can be observed that the lowest thermal conductivity is achieved for the Bi-doped Ca₃Co₄O_{9+δ} with three wt % of CeOₓ nanoparticles, and with the increasing concentration of CeOₓ nanoparticles, the thermal conductivity is increased continuously. The thermal conductivity of the sample with 3 wt % of CeOₓ is 1.66 W/mK at 323 K, which represents a 16.2% decrease in the thermal conductivity values compared to the undoped Ca₃Co₄O_{9+δ}. At 1073K, the thermal conductivity reduction is sustained, and the sample with 3 wt % of CeOₓ achieves a low value of 1.35 W/mK, which is equivalent to a 12.4% reduction compared to the pristine material and 11.8% compared to the Ca₃Co₄O_{9+δ}Bi_{0.25} samples without nanoparticles. Previous reports on CoSb₃ have shown similar effects of CeOₓ inclusions on the reduction of thermal conductivity values (Ref. 34). The main influence in the thermal conductivity values arises from the phonon scattering events from the dispersed CeOₓ nanoparticles at lower wt % concentration in the Ca₃Co₄O_{9+δ} ceramic. 4 and 5 wt % of CeOₓ show a larger thermal conductivity value. This might suggest that the agglomeration of the particles in the Ca₃Co₄O_{9+δ} matrix is not effective in reducing the thermal conductivity. Therefore, it is assumed that the phonon scattering effect is diminished by the agglomerated particles and the cluster of CeOₓ nanoparticles induces a higher thermal conductivity due to the intrinsic large thermal conductivity of the CeOₓ(with values ˜14 W/mK at 300K and ˜4 W/mK at 1073K for CeO₂ with a purity of 99.9% (Ref. 35). Consequently, the surface area and particle size of the CeO, nanoparticles have an exceptional impact on the thermal and electrical properties of the Ca₃Co₄O_{9+δ}.

The simultaneous increase of the electronic properties (increased S coupled with reduction of the ρ values) and the reduction of the thermal conductivity value in the K in the Ca₃Co₄O_{9+δ}Bi_{0.25+3} wt % CeOₓ samples produced a drastic increase in the ZT up to 1.27 at 1073K compared to the value of 0.42 for pristine Ca₃Co₄O₉ and peak ZT performance of 0.89 for the Ca₃Co₄O_{9+δ}Bi_{0.25} at 973 K. The increase in ZT represents a performance boost of 3.03 times compared to the undoped pristine ceramics, and the highest ZT reported for polycrystalline Ca₃Co₄O_{9+δ} materials. The results of this work surpass the ZT performance of the previously reported dual non-stoichiometric addition of Bi and stoichiometric substitution of Tb in the Ca₃Co₄O₉ (Ref. 30). The inward diffusion of Ca₃Co₄O_{9+δ}Bi_{0.25+3} wt % CeOₓ samples lead to dual doping into the Ca₃Co₄O_{9+δ} bulk but with the added benefit of nanoparticles providing phonon scattering events for the reduction of the thermal conductivity. This synergetic approach of nanoparticles and concurrent doping and diffusion doping leads to the record ZT performance of the polycrystalline ceramic.

The above example shows that CeOₓ can be introduced into the Bi-doped Ca₃Co₄O_{9+δ} as extraneous nanoinclusions. The synergetic interaction of doping Ce in the lattice and introducing the CeOₓ particles into the grain matrix significantly increased the electrical power factor from −0.60 mW/K²m to ˜1.6 mW/K²m at 1073K, and simultaneously decreased the thermal conductivity from −1.54 W/mK to 1.35 W/mK at 1073K. Overall, the ZT of Ca₃Co₄O_{9+δ}Bi_{0.25+3} wt % CeOₓ is reaching the record high ZT of 1.25 at 1073K. The disclosed compositions and methods provide intragranular Bi and Ce dopants, wherein the intergranular Bi dopants segregate, and that the disclosed nano-inclusions present an improved approaches for rendering ceramics to outperform their counterparts' single crystals.

It will be apparent to those skilled in the art that various modifications and variations can be made in the present disclosure without departing from the scope or spirit of the disclosure. Other aspects of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

What is claimed is:

1. A process to prepare a thermoelectric oxide ceramic material comprising a plurality nanoinclusions, the process comprising the steps of:
(a) preparing an aqueous thermoelectric oxide ceramic precursor solution;
(b) forming a thermoelectric oxide ceramic precursor sol-gel mixture from the thermoelectric oxide ceramic precursor solution;
(c) heating the thermoelectric oxide ceramic precursor sol-gel mixture to form a thermoelectric oxide ceramic precursor ash;
(d) preparing a thermoelectric oxide ceramic precursor powder using the thermoelectric oxide ceramic precursor ash;
(e) calcining the thermoelectric oxide ceramic precursor powder, thereby forming a calcined thermoelectric oxide ceramic precursor powder;
(f) preparing a thermoelectric oxide ceramic-nanoinclusion precursor by mixing the calcined thermoelectric oxide ceramic precursor powder with cerium oxide nanoparticles;
(g) forming a plurality of pellets of the thermoelectric oxide ceramic-nanoinclusion precursor; and
(h) sintering the plurality of pellets of the thermoelectric oxide ceramic-nanoinclusion precursor, thereby forming the thermoelectric oxide ceramic material comprising nanoinclusions;
wherein the aqueous thermoelectric oxide ceramic precursor solution comprises at least two thermoelectric oxide ceramic precursor salts;
wherein the at least two thermoelectric oxide ceramic precursor salts comprise at least two metal cations corresponding at least two metals in the thermoelectric oxide ceramic;
wherein the forming the thermoelectric oxide ceramic precursor sol-gel mixture comprises mixing a sol-gel polymer and a sol-gel acid with the aqueous thermoelectric oxide ceramic precursor solution; and
wherein the forming the plurality of pellets of the thermoelectric oxide ceramic-nanoinclusion precursor comprises applying pressure to the thermoelectric oxide ceramic-nanoinclusion precursor.

2. The process of claim 1, wherein the at least two thermoelectric oxide ceramic precursor salts comprise a calcium salt, a cobalt salt, and a bismuth salt.

3. The process of claim 1, wherein the at least two thermoelectric oxide ceramic precursor salts comprise a nitrate anion.

4. The process of claim 1, wherein the sol-gel polymer comprises polyethylene glycol.

5. The process of claim 1, wherein the sol-gel acid is nitric acid.

6. The process of claim 1, wherein the forming the thermoelectric oxide ceramic precursor sol-gel mixture further comprises mixing a sol-gel precursor with the aqueous thermoelectric oxide ceramic precursor solution.

7. The process of claim Error Reference source not found, wherein the sol-gel precursor comprises ethylene glycol.

8. The process of claim 1, wherein the heating the thermoelectric oxide ceramic precursor sol-gel mixture is carried out at a temperature from about 400° C. to about 600° C.

9. The process of claim 1, wherein the calcining is carried out at a temperature of about 600° C. to about 800° C.

10. The process of claim 1, wherein the forming the plurality of pellets of the thermoelectric oxide ceramic-nanoinclusion precursor comprises applying uniaxial pressure; and where the pressure applied is about 0.5 GPa to about 2 GPa.

11. The process of claim 1, wherein the sintering the plurality of pellets of the thermoelectric oxide ceramic-nanoinclusion precursor is carried out at about 850° C. to about 1100° C.

12. A thermoelectric oxide ceramic composition prepared by the process of claim 1.

13. The thermoelectric oxide ceramic composition of claim 12, wherein the composition comprises Ca₃₋ₓCeₓCo₄O_{9+δ}; and wherein x is about 0.05 to 0.5.

14. The thermoelectric oxide ceramic composition of claim 13, wherein the composition comprises Ca₃₋ₓCeₓCo₄O_{9+δ}; and wherein x is about 0.05 to 0.45.

15. The thermoelectric oxide ceramic composition of claim 13, wherein the composition comprises Ca₃₋ₓCeₓCo₄O_{9+δ}; and wherein x is about 0.1 to 0.5.

16. The thermoelectric oxide ceramic composition of claim 12, wherein the thermal conductivity is less than or equal to about 1.5 W/mK at 1073K.

17. The thermoelectric oxide ceramic composition of claim 12, wherein the composition comprises Ca₃₋ₓCo₄O_{9+δ}Bi_{y} and CeOₓ; wherein y is about 0.01 to about 0.4; and wherein CeOₓ is present in an amount of about 1 wt % to about 5 wt % based on the total weight of Ca₃₋ₓCo₄O_{9+δ}Bi_{y} and CeO.

18. The thermoelectric oxide ceramic composition of claim 12, wherein the Figure of Merit ZT at about 1073K is greater than or equal to about 1.0.

19. The thermoelectric oxide ceramic composition of claim 15, wherein the electrical power factor is about 1.5 mW/K²m to about 3 mW/K²m at 323K.

20. A solid-state energy conversion device comprising the disclosed thermoelectric ceramic oxide composition of claim 12.

21. The composition of claim 20, wherein the composition comprises Ca₃₋ₓCeₓCo₄O_{9+δ}; and wherein x is about 0.1 to 0.5.

22. A thermoelectric oxide ceramic composition, comprising:
Ca₃₋ₓCo₄O_{9+δ}Bi_{y} and CeOₓ;
wherein y is about 0.01 to about 0.4;
wherein x is about 0.1 to 0.5; and
wherein CeOₓ is present in an amount of about 1 wt % to about 5 wt % based on the total weight of Ca₃Co₄O_{9+δ}Bi_{y} and CeO.

23. The thermoelectric oxide ceramic composition of claim 22, wherein the CeOₓ comprises undoped CeOₓ, doped CeOₓ, or combinations thereof.

24. The thermoelectric oxide ceramic composition of claim 23, wherein the doped CeOₓ comprises a dopant selected from Sm, Gd, and combinations thereof.

25. The thermoelectric oxide ceramic composition of claim 22, wherein the Figure of Merit ZT at about 1073K is greater than or equal to about 0.5.

26. The thermoelectric oxide ceramic composition of claim 22, wherein the electrical power factor is about 1.0 mW/K²m to about 3 mW/K²m at about 323K.
